(19) United States
(12) Patent Application Publication
(10) Pub. No.: US 2025/0350857 A1
(43) Pub. Date: Nov. 13, 2025

(54) SOLID-STATE IMAGING DEVICE AND IMAGING APPARATUS

(71) Applicant: Nuvoton Technology Corporation Japan, Kyoto (JP)

(72) Inventors: Kenichi HAGA, Kyoto (JP); Takayasu KITO, Kyoto (JP); Makoto IKUMA, Kyoto (JP)

(21) Appl. No.: 19/271,041

(22) Filed: Jul. 16, 2025

Related U.S. Application Data
(63) Continuation of application No. PCT/JP2024/002494, filed on Jan. 26, 2024.
(60) Provisional application No. 63/442,311, filed on Jan. 31, 2023.
(60) Provisional application No. 63/442,317, filed on Jan. 31, 2023.

(51) Int. Cl. H04N 25/51; H04N 25/53; H04N 25/59; H04N 25/771; H04N 25/78

(52) U.S. Cl. CPC H04N 25/51; H04N 25/53; H04N 25/59; H04N 25/771; H04N 25/78

(57) ABSTRACT

A solid-state imaging device includes a pixel array in which a plurality of pixels are arranged in rows and columns. Each of the plurality of pixels includes: a photoelectric converter that converts received light into a signal charge; and a capacitance accumulator. Each of the plurality of pixels is configured to output M pixel signals each of which has a different gain. Control is performed on each of the plurality of pixels to cause the pixel to output N pixel signals out of the M pixel signals, N being an integer that is at least 2 and less than M.

### CROSS REFERENCE TO RELATED APPLICATIONS

This is a continuation application of PCT International Patent Application No. PCT/JP2024/002494 filed on Jan. 26, 2024, designating the United States of America, which is based on and claims priority of U.S. Provisional Patent Application No. 63/442,311 filed on Jan. 31, 2023 and U.S. Provisional Patent Application No. 63/442,317 filed on Jan. 31, 2023. The entire disclosures of the above-identified applications, including the specifications, drawings and claims are incorporated herein by reference in their entirety.

### FIELD

The present disclosure relates to solid-state imaging devices.

### BACKGROUND

A known solid-state imaging device increases a dynamic range by including a pixel array in which a plurality of pixels each of which outputs a plurality of pixel signals each of which has a different gain are arranged in rows and columns (e.g., see Patent Literatures (PTLs) 1 and 2).

### CITATION LIST

### Patent Literature

PTL 1: International Publication No. WO 2023/062947
PTL 2: Japanese Unexamined Patent Application Publication No. 2022-180791

### SUMMARY

### Technical Problem

Conventionally, in the solid-state imaging device thus configured, a readout time for the number of pixel signals×two frames is required to generate an image for one frame by performing correlated double sampling (CDS) on the plurality of pixel signals outputted from each pixel.

In the meantime, there has been a demand for solid-state imaging devices to achieve both speed-up of a frame rate and optimal dynamic range control.

In view of this, the present disclosure has an object to provide, for example, a solid-state imaging device that includes a pixel array in which a plurality of pixels each of which outputs M (M is an integer greater than or equal to 3) pixel signals each of which has a different gain are arranged in rows and columns, and that makes it possible to speed up a frame rate more than ever before.

### Solution to Problem

A solid-state imaging device according to one aspect of the present disclosure comprising: a pixel array in which a plurality of pixels are arranged in rows and columns, wherein each of the plurality of pixels includes: a photoelectric converter that converts received light into a signal charge; and a capacitance accumulator, each of the plurality of pixels is configured to output M pixel signals each of which has a different gain, and control is performed on each of the plurality of pixels to cause the pixel to output N pixel signals out of the M pixel signals, N being an integer that is at least 2 and less than M.

A solid-state imaging device according to one aspect of the present disclosure comprising: a pixel array in which a plurality of pixels are arranged in rows and columns; and an AD converter that is disposed for each of the columns in the pixel array, wherein each of the plurality of pixels is configured to output M pixel signals each of which has a different gain, and the AD converter converts each of at least one pixel signal out of the M pixel signals into a digital signal having a bit count fewer than a bit count of each of other pixel signals among the M pixel signals.

A solid-state imaging device according to one aspect of the present disclosure comprising: a pixel array in which a plurality of pixels are arranged in rows and columns; and an AD converter that is disposed for each of the columns in the pixel array, wherein each of the plurality of pixels includes: a photoelectric converter that converts received light into a signal charge; and a capacitance accumulator, each of the plurality of pixels is configured to output M pixel signals each of which has a different gain, control is performed on each of the plurality of pixels to cause the pixel to output N pixel signals out of the M pixel signals, N being an integer that is at least 2 and less than M, and the AD converter converts at least one pixel signal out of the N pixel signals into a digital signal having a bit count fewer than a bit count of each of other pixel signals among the N pixel signals.

An imaging apparatus according to one aspect of the present disclosure comprising the above solid-state imaging device, wherein the solid-state imaging device sequentially outputs image data based on the N pixel signals outputted by each of the plurality of pixels, the imaging apparatus further comprises a system controller that sequentially outputs, based on the image data sequentially outputted from the solid-state imaging device, a gain specification signal for specifying which N pixel signals each of the plurality of pixels is caused to output in the control performed on the pixel by the solid-state imaging device, and the solid-state imaging device sequentially controls each of the plurality of pixels, based on the gain specification signal sequentially outputted from the system controller.

An imaging apparatus according to one aspect of the present disclosure comprising the above solid-state imaging device, wherein the solid-state imaging device sequentially outputs image data based on the N pixel signals outputted by each of the plurality of pixels, the imaging apparatus further comprises a system controller that sequentially outputs, based on the image data sequentially outputted from the solid-state imaging device, a gain specification signal for specifying which N pixel signals each of the plurality of first pixels included in a corresponding one of the plurality of pixel blocks is caused to output in control performed on each of the plurality of pixel blocks by the solid-state imaging device, the gain specification signal being a signal for the pixel block, and the solid-state imaging device sequentially controls the first pixel included in the corresponding one of the plurality of pixel blocks, based on the gain specification signal for each of the plurality of pixel blocks sequentially outputted from the system controller.

### Advantageous Effects

Among solid-state imaging devices each including a pixel array in which a plurality of pixels each of which outputs M pixel signals each of which has a different gain are arranged in rows and columns, a solid-state imaging device etc. according to one aspect of the present disclosure makes it possible to achieve both speed-up of a frame rate and optimal dynamic range control.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram showing a configuration example of a solid-state imaging device according to Embodiment 1.

FIG. 2 is a circuit diagram showing a configuration example of a pixel according to Embodiment 1.

FIG. 3 is a correspondence table showing a correspondence relation between M gains, an ON state and an OFF state of M−1 connection transistors, and FDs each of which holds a signal charge corresponding to a pixel signal, according to Embodiment 1.

FIG. 4 is a table showing an example of a time required for outputting pixel signals and a time required for AD conversion according to Embodiment 1.

FIG. 5 is a table showing an example of a time required for outputting pixel signals and a time required for AD conversion according to Embodiment 1.

FIG. 6 is a graph showing an example of a relation between SN of a pixel signal corresponding to each of N gains and a dynamic range according to Embodiment 1.

FIG. 7 is a graph showing an example of a relation between SN of a pixel signal corresponding to each of N gains and a dynamic range according to Embodiment 1.

FIG. 8 is a table showing another example of a time required for outputting pixel signals and a time required for AD conversion according to Embodiment 1.

FIG. 9 is a table showing another example of a time required for outputting pixel signals and a time required for AD conversion according to Embodiment 1.

FIG. 10 is a block diagram showing a configuration example for reducing a time required for AD conversion in the solid-state imaging device according to Embodiment 1.

FIG. 11 is a circuit diagram showing a circuit configuration example for reducing a time required for AD conversion according to Embodiment 1.

FIG. 12 is a graph showing a relation between (i) an illuminance and an exposure time and (ii) values of digital signals obtained after AD conversion is performed on pixel signals, according to Embodiment 1.

FIG. 13 is a graph explaining an example of a method for improving SN of a pixel signal according to Embodiment 1.

FIG. 14 is a circuit diagram showing a configuration example of a pixel according to Embodiment 1 when M=3 and N=2.

FIG. 15 is a correspondence table showing a correspondence relation between three gains, an ON state and an OFF state of two connection transistors, and FDs each of which holds a signal charge corresponding to a pixel signal, when M=3 and N=2, according to Embodiment 1.

FIG. 16 is a timing chart showing an example of control timing for the pixel according to Embodiment 1 when M=3 and N=2.

FIG. 17 is a timing chart showing an example of control timing for the pixel according to Embodiment 1 when M=3 and N=2.

FIG. 18 is a block diagram showing a configuration example of an imaging apparatus according to Embodiment 1.

FIG. 19 is a timing chart showing an example of timing for exposure control performed by a system controller according to Embodiment 1.

FIG. 20 is a timing chart showing a state in which the pixel according to Embodiment 1 outputs pixel signals.

FIG. 21 is a block diagram showing a configuration example of a solid-state imaging device according to Embodiment 2.

FIG. 22 is a circuit diagram showing a configuration example of a pixel according to Embodiment 2.

FIG. 23 is a circuit diagram showing a configuration example of a pixel according to Embodiment 2 when M=3 and N=2.

FIG. 24 is a timing chart showing an example of control timing for the pixel according to Embodiment 2 when M=3 and N=2.

FIG. 25 is a timing chart showing an example of control timing for the pixel according to Embodiment 2 when M=3 and N=2.

FIG. 26 is a block diagram showing a configuration example of a solid-state imaging device according to Embodiment 3.

FIG. 27 is a block diagram showing a configuration example of an imaging apparatus according to Embodiment 3.

### DESCRIPTION OF EMBODIMENTS

### Circumstances Leading to One Aspect of the Present Disclosure

As stated above, there has been a demand for solid-state imaging devices to achieve both speed-up of a frame rate and optimal dynamic range control.

For this reason, the inventors repeatedly conducted intensive experiments and studies to allow a solid-state imaging device that includes a pixel array in which a plurality of pixels each of which outputs M pixel signals each of which has a different gain are arranged in rows and columns to achieve both the optimal dynamic range control and the speed-up of the frame rate.

As a result, the inventors gained knowledge that it is possible to achieve both the optimal dynamic range control and the speed-up of the frame rate by causing each pixel to select N (N is an integer greater than or equal to 2 and less than M) pixel signals from among the M pixel signals and output the N pixel signals.

Additionally, the inventors conducted further experiments and studies, based on this knowledge, and arrived at solid-state imaging devices etc. according to the present disclosure.

A solid-state imaging device according to one aspect of the present disclosure includes: a pixel array in which a plurality of pixels are arranged in rows and columns. Each of the plurality of pixels includes: a photoelectric converter that converts received light into a signal charge; and a capacitance accumulator. Each of the plurality of pixels is configured to output M pixel signals each of which has a different gain. Control is performed on each of the plurality of pixels to cause the pixel to output N pixel signals out of the M pixel signals, N being an integer that is at least 2 and less than M.

According to the solid-state imaging device thus configured, pixel signals outputted by each pixel are the N pixel signals that are included in and less numerous than the M pixel signals. For this reason, a pixel signal readout time is short, compared to a conventional solid-state image device including a configuration in which each of pixels outputs all of M pixel signals.

Accordingly, among solid-state imaging devices each including a pixel array in which a plurality of pixels each of which outputs M pixel signals each of which has a different gain are arranged in rows and columns, the solid-state imaging device thus configured makes it possible to achieve both the speed-up of the frame rate and the optimal dynamic range control more than ever before.

The capacitance accumulator may include: an overflow capacitance accumulator for accumulating the signal charge that overflows from the photoelectric converter; and at least one floating diffusion for converting the signal charge after conversion by the photoelectric converter into a voltage.

According to the solid-state imaging device thus configured, the signal charge that overflows from the photoelectric converter is accumulated in the at least one overflow capacitance accumulator.

Accordingly, the solid-state imaging device thus configured makes it possible to capture a subject having a higher illuminance, compared to a solid-state imaging device including no overflow capacitance accumulators.

Each of the plurality of pixels further may include: a transfer transistor that includes a source and a drain, one of which is connected to the photoelectric converter and an other of which is connected to one of the at least one floating diffusion; and a first connection transistor that includes a source and a drain, one of which is connected to the overflow capacitance accumulator and an other of which is connected to one of the at least one floating diffusion.

The control performed on each of the plurality of pixels may include shutter control for causing the pixel to perform a shutter operation, and the shutter control may be performed on each of the plurality of pixels to cause a period in which the overflow capacitance accumulator accumulates an electric charge and a period in which the photoelectric converter accumulates an electric charge to be substantially equal in length, regardless of the control performed on the pixel to cause the pixel to output the N pixel signals out of the M pixel signals.

Each of the plurality of pixels may further include an overflow transistor that includes a source and a drain, one of which is connected to the photoelectric converter and an other of which is connected to the overflow capacitance accumulator.

The at least one floating diffusion may include a plurality of floating diffusions, and each of the plurality of pixels may further include at least one second connection transistor that connects the plurality of floating diffusions.

Each of the plurality of pixels may further include a first reset transistor that includes a source and a drain, one of which is connected to the other of the source or the drain of the first connection transistor and an other of which is connected to a first pixel power source.

Each of the plurality of pixels may further include a second reset transistor that includes a source and a drain, one of which is connected to the other of the source or the drain of the first connection transistor and an other of which is connected to a second pixel power source that has a voltage different from a voltage of the first pixel power source.

The control may be performed on each of the plurality of pixels to cause the pixel to output N pixel signals out of the M pixel signals, the N pixel signals having gains adjacent to each other.

A solid-state imaging device according to one aspect of the present disclosure includes: a pixel array in which a plurality of pixels are arranged in rows and columns; and an AD converter that is disposed for each of the columns in the pixel array. Each of the plurality of pixels is configured to output M pixel signals each of which has a different gain. The AD converter converts each of at least one pixel signal out of the M pixel signals into a digital signal having a bit count fewer than a bit count of each of other pixel signals among the M pixel signals.

According to the solid-state imaging device thus configured, the AD converter converts each of the at least one pixel signal out of the M pixel signals into the digital signal having the bit count fewer than the bit count of each of the other pixel signals among the M pixel signals. For this reason, an AD conversion time is short, compared to a conventional solid-state imaging device configured not to convert at least one pixel signal into a digital signal having a bit count fewer than a bit count of each of other pixel signals.

Accordingly, among solid-state imaging devices each including a pixel array in which a plurality of pixels each of which outputs M pixel signals each of which has a different gain are arranged in rows and columns, the solid-state imaging device thus configured makes it possible to achieve both the speed-up of the frame rate and the optimal dynamic range control more than ever before.

The solid-state imaging device may further include a selection detection circuit that is disposed for each of the columns in the pixel array. The selection detection circuit may receive the M pixel signals from the pixel array, detect, among the M pixel signals, at least one pixel signal and at least one corrective pixel signal, and output the at least one pixel signal and the at least one corrective pixel signal to the AD converter. The AD converter may convert the at least one pixel signal into a digital signal, and convert the at least one corrective pixel signal into a first corrective digital signal having a bit count fewer than a bit count of the digital signal.

The solid-state imaging device may further include a high dynamic range (HDR) synthesis circuit. The AD converter may output the digital signal and the first corrective digital signal to the HDR synthesis circuit. The HDR synthesis unit may generate a second corrective digital signal by multiplying a value of the first corrective digital signal by a coefficient, and add up a value obtained by multiplying a value of the digital signal by a first mixing ratio and a value obtained by multiplying a value of the second corrective digital signal by a second mixing ratio. A sum of the first mixing ratio and the second mixing ratio may be 1.

A solid-state imaging device according to one aspect of the present disclosure includes: a pixel array in which a plurality of pixels are arranged in rows and columns; and an AD converter that is disposed for each of the columns in the pixel array. Each of the plurality of pixels includes: a photoelectric converter that converts received light into a signal charge; and a capacitance accumulator. Each of the plurality of pixels is configured to output M pixel signals each of which has a different gain. Control is performed on each of the plurality of pixels to cause the pixel to output N pixel signals out of the M pixel signals, N being an integer that is at least 2 and less than M. The AD converter converts at least one pixel signal out of the N pixel signals into a digital signal having a bit count fewer than a bit count of each of other pixel signals among the N pixel signals.

According to the solid-state imaging device thus configured, pixel signals outputted by each pixel are the N pixel signals that are included in and less numerous than the M pixel signals. For this reason, a pixel signal readout time is short, compared to a conventional solid-state image device including a configuration in which each of pixels outputs all of M pixel signals.

According to the solid-state imaging device thus configured, the AD converter converts the at least one pixel signal out of the N pixel signals into the digital signal having the bit count fewer than the bit count of each of the other pixel signals among the N pixel signals. For this reason, an AD conversion time is short, compared to the conventional solid-state imaging device configured not to convert the at least one pixel signal into the digital signal having the bit count fewer than the bit count of each of the other pixel signals.

Accordingly, among solid-state imaging devices each including a pixel array in which a plurality of pixels each of which outputs M pixel signals each of which has a different gain are arranged in rows and columns, the solid-state imaging device thus configured makes it possible to achieve both the speed-up of the frame rate and the optimal dynamic range control more than ever before.

The pixel array may include: a plurality of pixel blocks; and a control circuit that causes each of the plurality of pixel blocks to independently select and output the N pixel signals out of the M pixel signals. Each of the plurality of pixel blocks may include a plurality of first pixels that are arranged in rows and columns. The plurality of first pixels may be included in the plurality of pixels.

An imaging apparatus according to one aspect of the present disclosure is an imaging apparatus that includes the above solid-state imaging device. The solid-state imaging device sequentially outputs image data based on the N pixel signals outputted by each of the plurality of pixels. The imaging apparatus further includes a system controller that sequentially outputs, based on the image data sequentially outputted from the solid-state imaging device, a gain specification signal for specifying which N pixel signals each of the plurality of pixels is caused to output in the control performed on the pixel by the solid-state imaging device. The solid-state imaging device sequentially controls each of the plurality of pixels, based on the gain specification signal sequentially outputted from the system controller.

As with the above-described solid-state imaging device according to one aspect of the present disclosure, the imaging apparatus thus configured makes it possible to achieve both the speed-up of the frame rate and the optimal dynamic range control more than ever before.

An imaging apparatus according to one aspect of the present disclosure is an imaging apparatus that includes the above solid-state imaging device. The solid-state imaging device sequentially outputs image data based on the N pixel signals outputted by each of the plurality of pixels. The imaging apparatus further includes a system controller that sequentially outputs, based on the image data sequentially outputted from the solid-state imaging device, a gain specification signal for specifying which N pixel signals each of the plurality of first pixels included in a corresponding one of the plurality of pixel blocks is caused to output in control performed on each of the plurality of pixel blocks by the solid-state imaging device, the gain specification signal being a signal for the pixel block. The solid-state imaging device sequentially controls the first pixel included in the corresponding one of the plurality of pixel blocks, based on the gain specification signal for each of the plurality of pixel blocks sequentially outputted from the system controller.

As with the above-described solid-state imaging device according to one aspect of the present disclosure, the imaging apparatus thus configured makes it possible to achieve both the speed-up of the frame rate and the optimal dynamic range control more than ever before.

Hereinafter, specific examples of the solid-state imaging device etc. according to one aspect of the present disclosure are described with reference to the Drawings. Embodiments indicated below each show a different one of the specific examples of the present disclosure. As such, the numerical values, shapes, constituent elements, arrangements and connection states of constituent elements, steps (processes), orders of steps, etc. indicated in the following embodiments are mere examples, and are not intended to limit the present disclosure. In addition, the respective figures are schematic diagrams and are not necessarily precise illustrations. The same reference signs are assigned to substantially identical elements in each figure, and overlapping descriptions thereof are omitted or simplified.

### Embodiment 1

### Configuration Example 1 of Solid-State Imaging Device

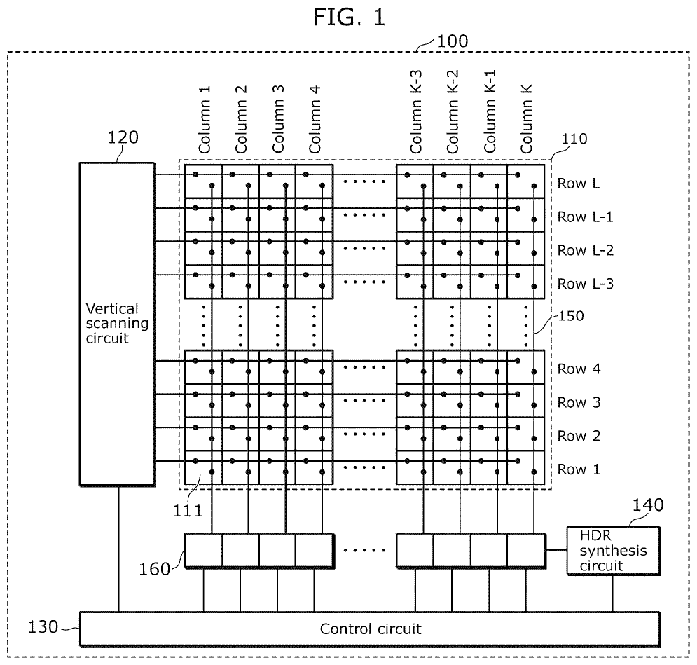

FIG. 1 is a block diagram showing a configuration example of solid-state imaging device 100 according to Embodiment 1.

As shown in FIG. 1, solid-state imaging device 100 includes pixel array 110, vertical scanning circuit 120, control circuit 130, high dynamic range (HDR) synthesis circuit 140, a plurality of vertical signal lines 150, and a plurality of AD converters 160.

Pixel array 110 is configured by arranging a plurality of pixels 111 in L (L is an integer greater than or equal to 2) rows and K (K is an integer greater than or equal to 2) columns.

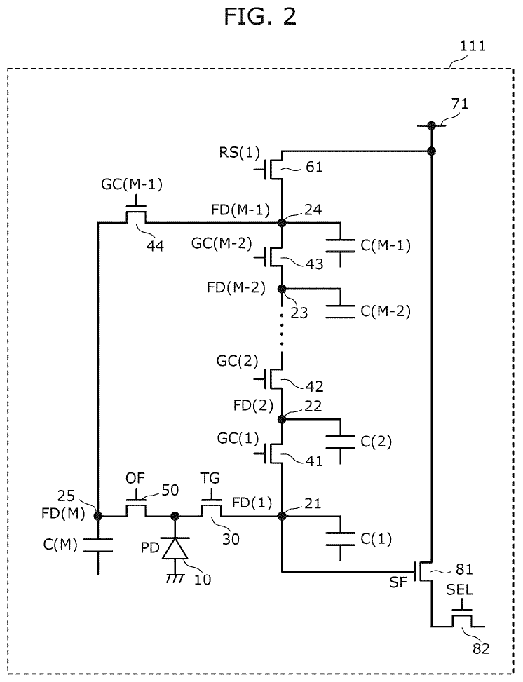

Each of the plurality of pixels 111 includes: photoelectric converter 10 that converts received light into a signal charge (not shown in FIG. 1, see FIG. 2 to be described later), that is, photoelectric converter 10 that generates a signal charge according to received light and accumulates the signal charge; and M (M is an integer greater than or equal to 3) capacitance accumulators (not shown in FIG. 1, see FIG. 2 to be described later, corresponding to capacitance accumulator 21 to capacitance accumulator 25 in FIG. 2) for accumulating the signal charge generated by photoelectric converter 10. Pixel 111 is configured to output M pixel signals each of which has a different gain. The detail of pixel 111 is described later.

Each of the plurality of vertical signal lines 150 is a line that extends in the column direction of pixel array 110. The plurality of vertical signal lines 150 correspond to the columns in pixel array 110 on a one-to-one basis. In other words, the number of the plurality of vertical signal lines 150 is K.

Each of the plurality of vertical signal lines 150 is connected to L pixels 111 arranged in the column direction in a corresponding one of the columns, and transmits a pixel signal outputted from one of L pixels 111 to a corresponding one of the plurality of AD converters 160.

Control circuit 130 controls vertical scanning circuit 120, HDR synthesis circuit 140, and the plurality of AD converters 160.

Control circuit 130 causes vertical scanning circuit 120 to cause each of the plurality of pixels 111 to output N (N is an integer greater than or equal to 2 and less than M) pixel signals out of M pixel signals.

At this time, control circuit 130 causes vertical scanning circuit 120 to cause each of the plurality of pixels 111 to: convert a signal charge corresponding to a state in which pixel 111 is reset into a reference voltage corresponding to each of gains, and output a pixel signal indicating the reference voltage after conversion; and convert a signal charge generated by photoelectric converter 10 in an exposure period into a voltage corresponding to each of gains, and output a pixel signal indicating the voltage after conversion.

Hereinafter, a series of operations from when pixel 111 is caused to convert a signal charge into a voltage corresponding to each gain to when pixel 111 is caused to output a pixel signal indicating the voltage after conversion is expressed as reading out of a pixel signal corresponding to each gain.

A pixel signal corresponding to each gain includes a reset component and a signal component. In each gain, a portion of the pixel signal indicating a reference voltage is a reset component, and a portion of the pixel signal indicating a voltage into which a signal component generated by photoelectric converter 10 in an exposure period is converted is a signal component.

It should be noted that vertical scanning circuit 120 may include at least one or all of functions of control circuit 130.

The plurality of AD converters 160 correspond to K vertical signal lines 150 on a one-to-one basis. In other words, the number of the plurality of AD converters 160 is K.

Each of K AD converters 160 is connected to the corresponding vertical signal line 150.

K AD converters 160 convert K analog pixel signals outputted from K pixels 111 via K vertical signal lines 150 per row into K digital pixel signals. Next, K AD converters 160 output the K digital pixel signals after AD conversion to HDR synthesis circuit 140.

It should be noted that AD conversion is performed in combination with correlated dual sampling that removes reset noise etc. at the time of a pixel signal readout operation by calculating a difference between a result of AD conversion of a pixel signal including a reset component and a result of AD conversion of a pixel signal including a signal component.

HDR synthesis circuit 140 performs HDR synthesis on pixel signals outputted from the plurality of AD converters 160, to generate an image.

Solid-state imaging device 100 thus configured causes the K AD converters 160 to perform, in parallel, AD conversion on K pixel signals outputted from K pixels 111 in one row via the K vertical signal lines 150 after the K vertical signal lines 150 converge, and output K digital pixel signals after AD conversion for the one row to HDR synthesis circuit 140.

Solid-state imaging device 100 repeats the above-described operation in one horizontal scanning period until reading out of N pixel signals corresponding to gain x to gain x+N−1 (x is an integer greater than or equal to 1 and less than M−N+1) and AD conversion of the N pixel signals are completed.

Solid-state imaging device 100 further repeats the above-described operation sequentially for each of row 1 to row L in pixel array 110 per unit of one horizontal scanning period.

Solid-state imaging device 100 thus configured sequentially outputs image data based on the N pixel signals outputted by each of the plurality of pixels 111.

Although the present embodiment is described on the premise that solid-state imaging device 100 repeats the above-described operation sequentially for each of row 1 to row L in pixel array 110 per unit of one horizontal scanning period, solid-state imaging device 100 may repeat the above-described operation for every two or more rows of row 1 to row L in pixel array 110, or solid-state imaging device 100 may operate in a global shutter mode in which pixel signals are read out in all rows in the same time period.

Moreover, although the present embodiment is described based on the premise that the numbers of the plurality of vertical signal lines 150 and the plurality of AD converters 160 are K, and the plurality of vertical signal lines 150 correspond to the plurality of AD converters 160 on a one-to-one basis, the number of the plurality of vertical signal lines 150 or the number of the plurality of AD converters 160 or both may exceed K, and the plurality of vertical signal lines 150 need not correspond to the plurality of AD converters 160 on a one-to-one basis.

### Configuration Example 1 of Pixel

FIG. 2 is a circuit diagram showing a configuration example of pixel 111.

As stated above, pixel 111 includes photoelectric converter 10 and the M capacitance accumulators (corresponding to capacitance accumulator 21 to capacitance accumulator 25 in FIG. 2).

Photoelectric converter 10 is achieved by, for example, a photodiode that includes a PN junction.

Each of capacitance accumulator 21 to capacitance accumulator 25, which are the M capacitance accumulators, is achieved by, for example, a floating diffusion layer.

Each of capacitance accumulator 21 to capacitance accumulator 25, which are the M capacitance accumulators, includes: at least one overflow capacitance accumulator for accumulating a signal charge that overflows from photoelectric converter 10; and at least one floating diffusion for converting a signal charge after conversion by photoelectric converter 10 into a voltage, the at least one floating diffusion being different from the at least one overflow capacitance accumulator.

The following description is based on the premise that the at least one overflow capacitance accumulator is capacitance accumulator 25, and the at least one floating diffusion different from the at least one overflow capacitance accumulator is at least one of M−1 capacitance accumulators including capacitance accumulator 21 to capacitance accumulator 24.

Hereinafter, capacitance accumulator 25 is also referred to as overflow capacitance accumulator 25 or FD(M), and capacitance accumulator 21 to capacitance accumulator 24 are also referred to as floating diffusion 21 to floating diffusion 24 or FD(1) to FD(M−1).

Additionally, as shown in FIG. 2, FD(1) to FD(M) include capacitor C(1) to capacitor C(M), respectively.

As shown in FIG. 2, pixel 111 further includes transfer transistor 30 and first connection transistor 44.

Transfer transistor 30 includes a source and a drain, one of which is connected to photoelectric converter 10 and an other of which is connected to a floating diffusion (here, floating diffusion 21) among the at least one floating diffusion.

Transfer transistor 30 is an NMOS transistor, and the gate of transfer transistor 30 is driven by control signal TG outputted from vertical scanning circuit 120.

When a logic level of the gate of transfer transistor 30 becomes low, transfer transistor 30 enters a non-conductive state; and when the logic level of the gate of transfer transistor 30 becomes high, transfer transistor 30 enters a conductive state.

Hereinafter, a transistor being in the conductive state is also referred to as a transistor being ON, and a transistor being in the non-conductive state is also referred to as a transistor being OFF.

When transfer transistor 30 enters the conductive state, a signal charge accumulated in photoelectric converter 10 is transferred to floating diffusion 21 via transfer transistor 30. When at least other one floating diffusion electrically connected to floating diffusion 21 is present, the signal charge accumulated in photoelectric converter 10 is also transferred to the at least other one floating diffusion.

First connection transistor 44 includes a source and a drain, one of which is connected to an overflow capacitance accumulator (here, overflow capacitance accumulator 25) among the at least one overflow accumulator and an other of which is connected to a floating diffusion (here, floating diffusion 24) among the at least one floating diffusion.

First connection transistor 44 is an NMOS transistor, and the gate of first connection transistor 44 is driven by control signal GC(M−1) outputted from vertical scanning circuit 120.

When a logic level of the gate of first connection transistor 44 becomes low, first connection transistor 44 enters the non-conductive state; and when the logic level of the gate of first connection transistor 44 becomes high, first connection transistor 44 enters the conductive state.

When first connection transistor 44 enters the conductive state, overflow capacitance accumulator 25 and floating diffusion 24 are electrically connected.

As shown in FIG. 2, pixel 111 further includes overflow transistor 50.

Overflow transistor 50 includes a source and a drain, one of which is connected to photoelectric converter 10 and an other of which is connected to overflow capacitance accumulator 25.

Overflow transistor 50 is an NMOS transistor, and the gate of overflow transistor 50 is driven by control signal OFF outputted from vertical scanning circuit 120.

For this reason, it is possible to control the height of a potential barrier between photoelectric converter 10 and overflow capacitance accumulator 25 by controlling a voltage of the gate of overflow transistor 50.

As shown in FIG. 2, pixel 111 further includes M−2 second connection transistors (here, second connection transistor 41 to second connection transistor 43).

The M−2 second connection transistors (here, second connection transistor 41 to second connection transistor 43) connect M−1 floating diffusions (here, floating diffusion 21 to floating diffusion 24) in series.

Here, floating diffusion 24 located at one end of the M−1 floating diffusions connected in series is connected to the other of the source or the drain of first connection transistor 44, and floating diffusion 21 located at an other end of the M−1 floating diffusions connected in series is connected to the other of the source or the drain of transfer transistor 30.

Second connection transistor 41 to second connection transistor 43 are NMOS transistors, and the gates of second connection transistor 41 to second connection transistor 43 are driven by control signals GC(1) to control signal GC(M−2) outputted from vertical scanning circuit 120, respectively.

When respective logic levels of the gates of second connection transistor 41 to second connection transistor 43 become low, second connection transistor 41 to second connection transistor 43 enter the non-conductive state; and when the respective logic levels of the gates of second connection transistor 41 to second connection transistor 43 become high, second connection transistor 41 to second connection transistor 43 enter the conductive state.

When each of second connection transistor 41 to second connection transistor 43 enters the conductive state, a floating diffusion connected to one of the source or the drain of the second connection transistor and a floating diffusion connected to an other of the source or the drain of the second connection transistor are electrically connected.

First connection transistor 44 and second connection transistor 41 to second connection transistor 43 each are an example of a transistor that switches between gains.

Hereinafter, when there is no need to clearly distinguish between second connection transistor 41 to second connection transistor 43 and first connection transistor 44, second connection transistor 41 to second connection transistor 43 and first connection transistor 44 are simply also referred to as connection transistors. In this case, second connection transistor 41 to second connection transistor 43 and first connection transistor 44 are also referred to as connection transistor GC(1) to connection transistor GC(M−2) and connection transistor GC(M−1), respectively.

As shown in FIG. 2, pixel 111 further includes first reset transistor 61, amplifier transistor 81, and selection transistor 82.

First reset transistor 61 includes a source and a drain, one of which is connected to the other of the source or the drain of first connection transistor 44 and an other of which is connected to first pixel power source 71.

First reset transistor 61 is an NMOS transistor, and the gate of first reset transistor 61 is driven by control signal RS(1) outputted from vertical scanning circuit 120.

When a logic level of the gate of first reset transistor 61 becomes low, first reset transistor 61 enters the non-conductive state; and when the logic level of the gate of first reset transistor 61 becomes high, first reset transistor 61 enters the conductive state.

When first reset transistor 61 enters the conductive state, floating diffusion 24 and floating diffusion 21 to floating diffusion 23 that are electrically connected to floating diffusion 24, overflow capacitance accumulator 25 that is electrically connected to floating diffusion 24, or photoelectric converter 10 are reset at a voltage of first pixel power source 71.

Amplifier transistor 81 includes a gate connected to floating diffusion 21, a drain connected to first pixel power source 71, and a source connected to the drain of selection transistor 82.

Amplifier transistor 81 is an NMOS transistor. Amplifier transistor 81 and a constant current source (not shown in the figure) connected to amplifier transistor 81 via selection transistor 82 (to be described later) and disposed in vertical line 150 constitute a source follower circuit. Accordingly, when selection transistor 82 is in the conductive state, amplifier transistor 81 outputs a pixel signal corresponding to a voltage of floating diffusion 24 to vertical signal line 150.

Selection transistor 82 includes a drain connected to the source of amplifier transistor 81 and a source connected to vertical signal line 150.

Selection transistor 82 is an NMOS transistor, and the gate of selection transistor 82 is driven by vertical scanning circuit 120.

When a logic level of the gate of selection transistor 82 becomes low, selection transistor 82 enters the non-conductive state; and when the logic level of the gate of selection transistor 82 becomes high, selection transistor 82 enters the conductive state.

When selection transistor 82 enters the conductive state, a pixel signal outputted from amplifier transistor 81 is outputted to vertical signal line 150 via selection transistor 82. In other words, when selection transistor 82 enters the conductive state, pixel 111 enters a selective state.

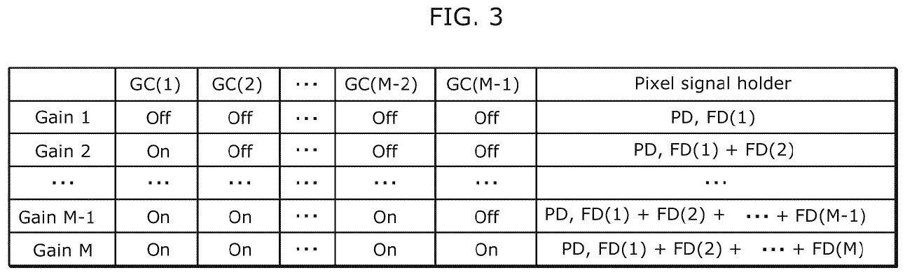

FIG. 3 is a correspondence table showing a correspondence relation between (1) M gains, (2) an ON state and an OFF state of connection transistor GC(1) to connection transistor GC(M−1) when pixel 111 is outputting a pixel signal corresponding to each of the M gains, and (3) FD(1) to FD(M) each of which holds a signal charge corresponding to the pixel signal.

As shown in FIG. 3, when pixel 111 outputs a pixel signal corresponding to gain 1, connection transistor GC(1) to connection transistor GC(M−1) are in the OFF state. Before a signal charge generated by photoelectric converter 10 is transferred to FD(1), the pixel signal including a reset component is outputted from pixel 111, and after the signal charge generated by photoelectric converter 10 is transferred to FD(1) by transfer transistor 30, the pixel signal including a signal component is outputted from pixel 111.

Moreover, as shown in FIG. 3, when pixel 111 outputs a pixel signal corresponding to gain 2, connection transistor GC(1) is in the ON state and connection transistor GC(2) to connection transistor GC(M−1) are in the OFF state. Before a signal charge generated by photoelectric converter 10 is transferred to FD(1) and FD(2), the pixel signal including a reset component is outputted from pixel 111, and after the signal charge generated by photoelectric converter 10 is transferred to FD(1) and FD(2) by transfer transistor 30, the pixel signal including a signal component is outputted from pixel 111.

Furthermore, as shown in FIG. 3, when pixel 111 outputs a pixel signal corresponding to gain M−1, connection transistor GC(1) to connection transistor GC(M−2) are in the ON state and connection transistor GC(M−1) is in the OFF state. Before a signal charge generated by photoelectric converter 10 is transferred to FD(1) to FD(M−1), the pixel signal including a reset component is outputted from pixel 111, and after the signal charge generated by photoelectric converter 10 is transferred to FD(1) to FD(M−1) by transfer transistor 30, the pixel signal including a signal component is outputted from pixel 111.

Moreover, as shown in FIG. 3, when pixel 111 outputs a pixel signal corresponding to gain M, connection transistor GC(1) to connection transistor GC(M−1) are in the ON state. After the pixel signal including a signal component corresponding to a total signal charge obtained by adding up a signal charge generated by photoelectric converter 10 and transferred to FD(1) to FD(M−1) in advance by transfer transistor 30 and a signal charge that overflows from photoelectric converter 10 and is accumulated in FD(M) is outputted from pixel 111, and a signal charge accumulated in FD(1) to FD(M) is discharged to first pixel power source 71 via first reset transistor 61, the pixel signal including a reset component is outputted from pixel 111.

### <Readout Operation Time and Dynamic Range>

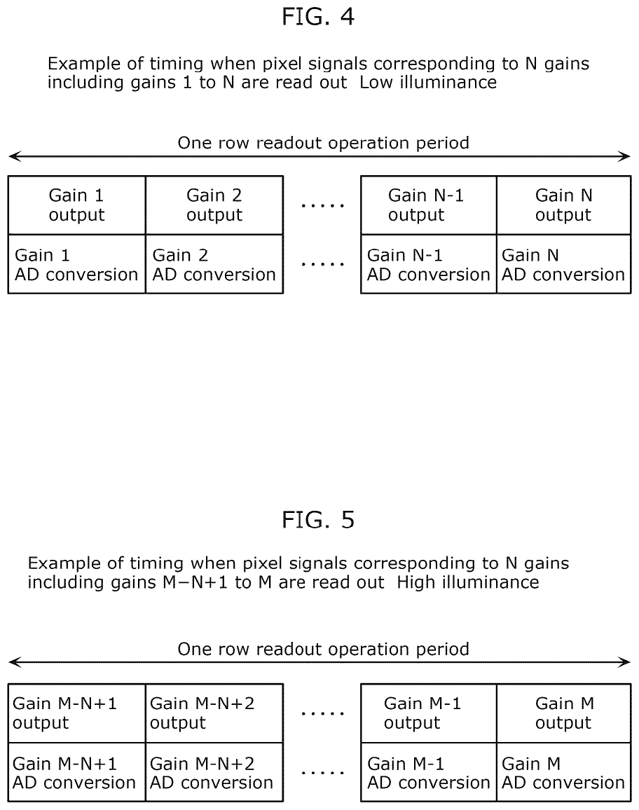

FIG. 4 and FIG. 5 are tables each showing an example of a time required for outputting pixel signals and a time required for AD conversion in a series of operations from when pixel 111 outputs pixel signals corresponding to N gains to vertical signal line 150 to when AD converter 160 performs AD conversion on the pixel signals outputted, in the case where solid-state imaging device 100 captures a subject.

FIG. 4 is a table when pixel 111 outputs pixel signals corresponding to gain 1 to gain N in the case where solid-state imaging device 100 captures a subject having a relatively low illuminance. FIG. 5 is a table when pixel 111 outputs pixel signals corresponding to gain M−N+1 to gain M in the case where solid-state imaging device 100 captures a subject having a relatively high illuminance.

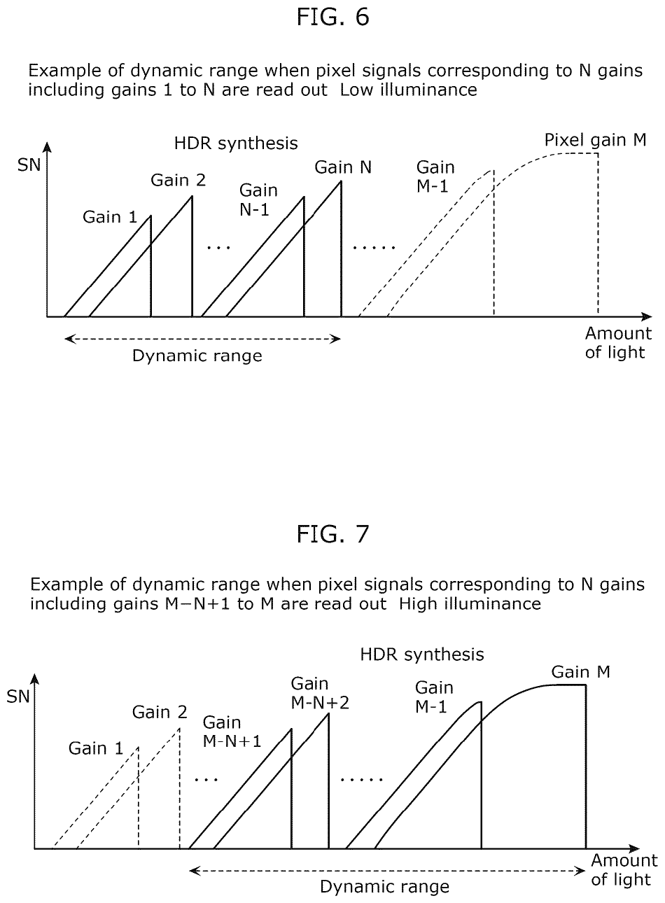

FIG. 6 and FIG. 7 are graphs each showing an example of a relation between SN of a pixel signal corresponding to each of N gains and a dynamic range in a series of operations from when pixel 111 outputs the pixel signals corresponding to the N gains to vertical signal line 150 to when AD converter 160 performs AD conversion on the pixel signals outputted, in the case where solid-state imaging device 100 captures a subject.

FIG. 6 is a graph when pixel 111 outputs pixel signals corresponding to gain 1 to gain N in the case where solid-state imaging device 100 captures a subject having a relatively low illuminance. FIG. 7 is a graph when pixel 111 outputs pixel signals corresponding to gain M−N+1 to gain M in the case where solid-state imaging device 100 captures a subject having a relatively high illuminance.

As shown in FIG. 6 and FIG. 7, vertical scanning circuit 120 causes pixel 111 to output, out of M pixel signals, N pixel signals including gains adjacent to each other.

Accordingly, it is possible to reduce a difference in SN in a boundary (transition region) of each of the N pixel signals.

As shown in FIG. 7, when pixel 111 outputs the pixel signals corresponding to gain M−N+1 to gain M, pixel 111 outputs the pixel signals each including a signal component corresponding to a total signal charge obtained by adding up a signal charge transferred to FD(1) to FD(M−1) in advance by transfer transistor 30 and a signal charge that overflows from photoelectric converter 10 and is accumulated in FD(M). For this reason, solid-state imaging device 100 makes it possible to capture a subject having a higher illuminance, compared to a solid-state imaging device not including FD(M) capable of accumulating a signal charge that overflows from photoelectric converter 10.

As shown in FIG. 4 to FIG. 7, solid-state imaging device 100 generates an image by causing each pixel 111 to output, out of M pixel signals, N pixel signals corresponding to N gains, causing AD converter 160 to perform AD conversion on the N pixel signals outputted from each pixel 111, and causing HDR synthesis circuit 140 to perform HDR synthesis on the pixel signals after the AD conversion by AD converter 160.

Accordingly, among solid-state imaging devices each including a pixel array in which a plurality of pixels each of which outputs M pixel signals each of which has a different gain are arranged in rows and columns, solid-state imaging device 100 thus configured makes it possible to speed up a frame rate, compared to a conventional solid-state imaging device that reads out all of M pixel signals.

### <Reduction of Bit Width in AD Conversion>

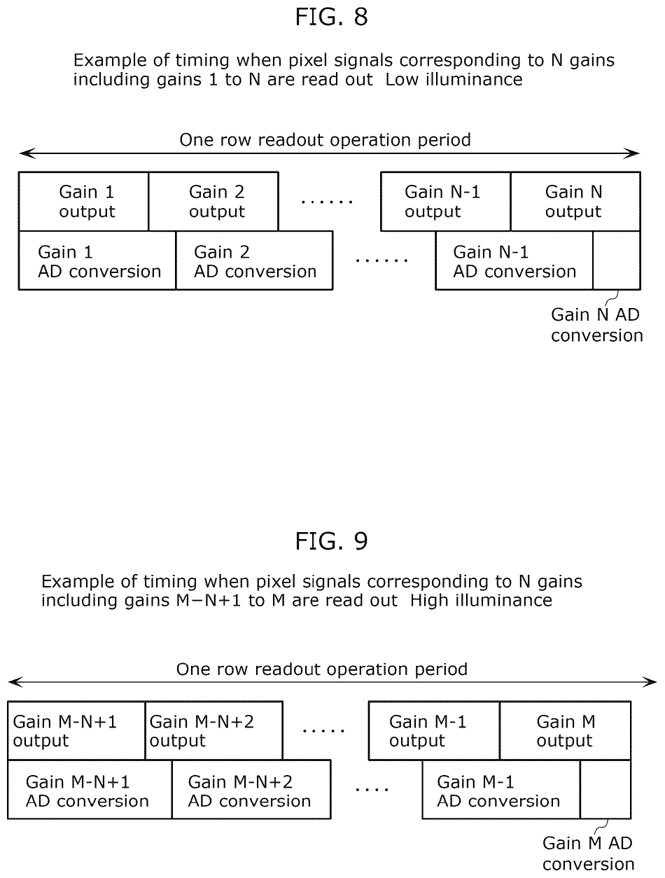

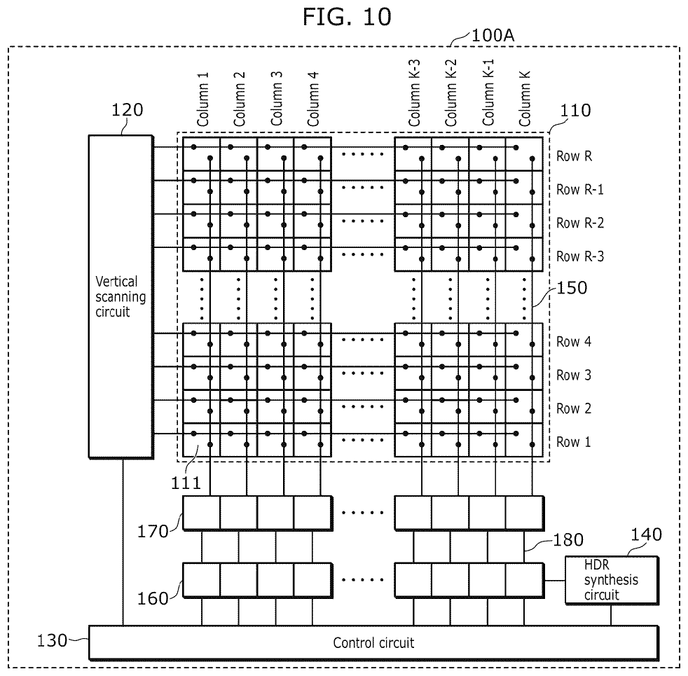

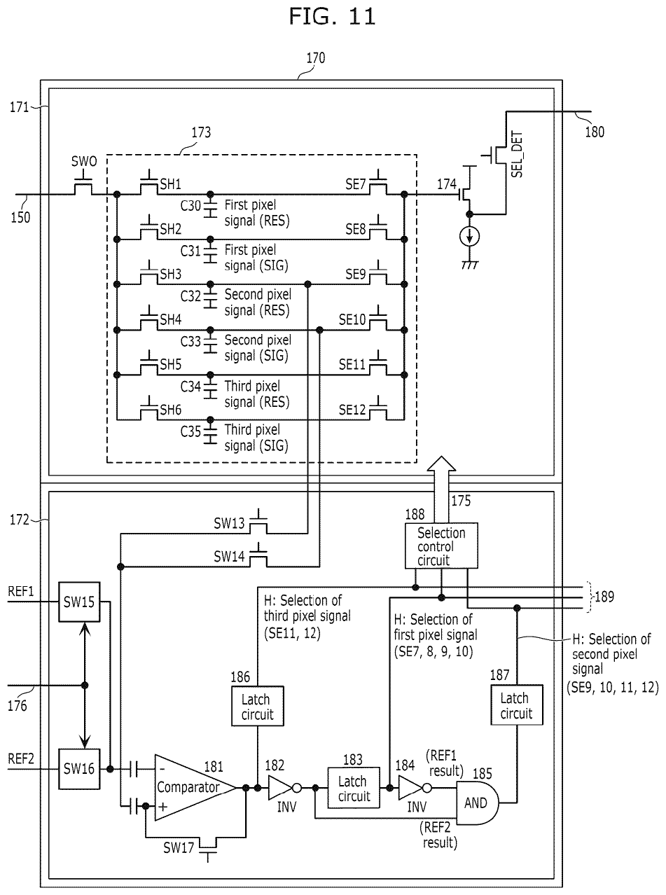

FIG. 8 and FIG. 9 are tables each showing another example of a time required for outputting pixel signals and a time required for AD conversion in a series of operations from when pixel 111 outputs pixel signals corresponding to N gains to vertical signal line 150 to when AD converter 160 performs AD conversion on the N pixel signals outputted, in the case where solid-state imaging device 100 captures a subject.

FIG. 8 and FIG. 9 each show an example in which the time required for AD conversion exceeds the time required for outputting pixel signals, whereas FIG. 4 and FIG. 5 each show an example in which the time required for AD conversion does not exceed the time required for outputting pixel signals.

FIG. 8 is a table when pixel 111 outputs pixel signals corresponding to gain 1 to gain N in the case where solid-state imaging device 100 captures a subject having a relatively low illuminance. FIG. 9 is a table when pixel 111 outputs pixel signals corresponding to gain M−N+1 to gain M in the case where solid-state imaging device 100 captures a subject having a relatively high illuminance.

As shown in FIG. 8, in the case where the time required for AD conversion exceeds the time required for outputting pixel signals, when AD converter 160 performs AD conversion on a pixel signal corresponding to gain N, AD converter 160 causes a time required for AD conversion on the pixel signal corresponding to gain N to be shorter than a time required for AD conversion on pixel signals corresponding to N−1 gains, by converting the pixel signal corresponding to gain N to a pixel signal having a bit count fewer than a bit count of each of the pixel signals corresponding to the N−1 gains after AD conversion.

Accordingly, it is possible to speed up a frame rate, compared to a case in which the time required for AD conversion on the pixel signal corresponding to gain N is not caused to be shorter than the time required for AD conversion on the pixel signals corresponding to the N−1 gains.

As shown in FIG. 9, in the case where the time required for AD conversion exceeds the time required for outputting pixel signals, when AD converter 160 performs AD conversion on a pixel signal corresponding to gain M, AD converter 160 causes a time required for AD conversion on the pixel signal corresponding to gain M to be shorter than a time required for AD conversion on pixel signals corresponding to N−1 gains, by converting the pixel signal corresponding to gain M to a pixel signal having a bit count fewer than a bit count of each of the pixel signals corresponding to the N−1 gains after AD conversion.

Accordingly, it is possible to speed up a frame rate, compared to a case in which the time required for AD conversion on the pixel signal corresponding to gain M is not caused to be shorter than the time required for AD conversion on the pixel signals corresponding to the N−1 gains.

As stated above, when a time required for AD conversion exceeds a time required for outputting pixel signals, AD converter 160 makes it possible to achieve the speed-up of a frame rate by causing a time required for AD conversion on a pixel signal corresponding to a gain to be shorter than a time required for AD conversion on pixel signals corresponding to N−1 gains, compared to a case in which the time required for AD conversion on the pixel signal corresponding to the gain is not caused to be shorter than the time required for AD conversion on the pixel signals corresponding to the N−1 gains.

FIG. 10 is a block diagram showing a specific configuration example of solid-state imaging device 100A that converts at least one pixel signal out of N pixel signals into a digital signal having a bit count fewer than a bit count of each of the remaining pixel signals.

As shown in FIG. 10, solid-state imaging device 100A is configured by adding a plurality of selection detection circuits 170 and a plurality of signal lines 180 to solid-state imaging device 100 shown in FIG. 1.

In a corresponding column, each of the plurality of vertical signal lines 150 transmits, to a corresponding one of the plurality of selection detection circuits 170, a pixel signal outputted from one of L pixels 111 arranged in the column direction.

Each of the plurality of selection detection circuits 170 identifies an optimal pixel signal and a corrective pixel signal for correcting the optimal pixel signal among N pixel signals. Selection detection circuits 170 transmits the optimal pixel signal to a corresponding one of the plurality of AD converters 160 via a corresponding one of the plurality of signal lines 180, and then transmits the corrective pixel signal to corresponding AD converter 160 via corresponding signal line 180.

Each of the plurality of AD converters 160 converts a corrective pixel signal into a digital signal having a bit count fewer than a bit count of an optimal pixel signal. Reasons for converting a corrective pixel signal into a digital signal having a bit count fewer than a bit count of an optimal pixel signal are described later.

The plurality of selection detection circuits 170 correspond to K vertical signal lines 150 on a one-to-one basis, and correspond to K AD converters 160 on a one-to-one basis. In other words, the number of the plurality of selection detection circuits 170 is K.

The plurality of signal lines 180 correspond to K selection detection circuits 170 on a one-to-one basis, and correspond to K AD converters 160 on a one-to-one basis. In other words, the number of the plurality of signal lines 180 is K.

Although solid-state imaging device 100A is described based on the premise the numbers of AD converters 160, selection detection circuits 170, and signal lines 180 are K, and selection detection circuits 170 correspond to K vertical signal lines 150, one or at least two of the numbers of AD converters 160, selection detection circuits 170, and signal lines 180 may exceed K, vertical signal lines 150 need not correspond to selection detection circuits 170 on a one-to-one basis, and selection detection circuits 170 need not correspond to AD converters 160 on a one-to-one basis.

FIG. 11 shows an example of selection detection circuit 170 when N=3.

Selection detection circuit 170 includes: selection circuit 171 that includes sample and hold circuit SH 173 that holds a plurality of pixel signals, and selects a pixel signal from among the plurality of pixel signals; and detection circuit 172 that detects at least one pixel signal among the plurality of pixel signals.

A plurality of pixel signals from pixel 111 are held in sample and hold circuit SH 173.

First, an example of sample and hold circuit SH 173 is described.

In sample and hold circuit SH 173, with switch element SW0 being in the ON state, a pixel signal is inputted to a sample and hold capacitance element (C30, C31, C32, C33, C34, C35) via vertical signal line 150 and a sample and hold switch element (SH1, SH2, SH3, SH4, SH5, SH6), and then inputted to the gate of amplifier transistor SF 174 via a readout selection switch element (SE7, SE8, SE9, SE10, SE11, SE12). Output of amplifier transistor SF 174 is connected to signal line 180 via selection transistor SEL_DET.

The sample and hold switch element (SH1, SH2, SH3, SH4, SH5, SH6) is a switch transistor that is turned ON and OFF according to sample and hold switch control signal φSH. When the sample and hold switch element is OFF, a pixel signal is held in the sample and hold capacitance element (C30, C31, C32, C33, C34, C35). In other words, address selection when the pixel signal is held in the sample and hold capacitance element (C30, C31, C32, C33, C34, C35) is performed according to sample and hold switch control signal φSH.

The readout selection switch element (SE7, SE8, SE9, SE10, SE11, SE12) is a switch transistor that is turned ON and OFF according to signal selection signal 175 ((φSE). When the readout selection switch element is ON, a pixel signal held in the sample and hold capacitance element (C30, C31, C32, C33, C34, C35) is inputted to the gate of amplifier transistor SF 174. In other words, address selection when a pixel signal is read out from the sample and hold capacitance element (C30, C31, C32, C33, C34, C35) is performed according to signal selection signal 175 ((φSE).

Selection transistor SEL_DET is a switch transistor that is turned ON and OFF according to selection control signal φSEL_DET. When a logic level of selection control signal φSEL_DET is high, selection transistor SEL_DET electrically connects the source of amplifier transistor SF 174 and signal line 180.

Here, a reset component included in a first pixel signal corresponding to the highest gain among three pixel signals is held in a sample and hold capacitance element (C30). On the other hand, a signal component included in the first pixel signal is held in a sample and hold capacitance element (C31).

A reset component included in a second pixel signal corresponding to the second highest gain among the three pixel signals is held in a sample and hold capacitance element (C32). On the other hand, a signal component included in the second pixel signal is held in sample and hold capacitance element (C33).

A reset component included in a third pixel signal corresponding to the lowest gain among the three pixel signals is held in a sample and hold capacitance element (C34). On the other hand, a signal component included in the third pixel signal is held in sample and hold capacitance element (C35).

Next, detection circuit 172 compares a value obtained by subtracting the reset component (held in C32) from the signal component (held in C33) included in the second pixel signal held in sample and hold circuit SH 173, a first reference value (REF1) of a boundary portion between the first pixel signal and the second pixel signal, and a second reference value (REF2) of a boundary portion between the second pixel signal and the third pixel signal. In this manner, detection circuit 172 detects an optimal pixel signal and a corrective pixel signal among the three pixel signals, and inputs signal selection signal 175 ((φSE) to selection circuit 171.

Here, when the first pixel signal is detected as the optimal pixel signal, the second pixel signal is detected as the corrective pixel signal; and when the second pixel signal is detected as the optimal pixel signal, the third pixel signal is detected as the corrective pixel signal. When the third pixel signal is detected as the optimal pixel signal, the corrective pixel signal is not detected.

Then, selection circuit 171 controls the readout selection switch element, based on signal selection signal 175 ((φSE).

For example, when the first pixel signal is the optimal pixel signal, readout selection switch element SE7 is turned ON and the reset component is outputted to signal line 180 via amplifier transistor SF 174 and selection transistor SEL_DET. Likewise, readout selection switch element SE8 is turned ON and the signal component is outputted to signal line 180 via amplifier transistor SF 174 and selection transistor SEL_DET. Next, since the second pixel signal is the corrective pixel signal, readout selection switch element SE9 is turned ON and the reset component is outputted to signal line 180 via amplifier transistor SF 174 and selection transistor SEL_DET. In a similar manner, readout selection switch element SE10 is turned ON and the signal component is outputted to signal line 180 via amplifier transistor SF 174 and selection transistor SEL_DET.

When the second pixel signal is the optimal pixel signal, readout selection switch element SE9 is turned ON and the reset component is outputted to signal line 180 via amplifier transistor SF 174 and selection transistor SEL_DET. Likewise, readout selection switch element SE10 is turned ON and the signal component is outputted to signal line 180 via amplifier transistor SF 174 and selection transistor SEL_DET. Next, since the third pixel signal is the corrective pixel signal, readout selection switch element SE11 is turned ON and the reset component is outputted to signal line 180 via amplifier transistor SF 174 and selection transistor SEL_DET. In a similar manner, readout selection switch element SE12 is turned ON and the signal component is outputted to signal line 180 via amplifier transistor SF 174 and selection transistor SEL_DET.

When the third pixel signal is the optimal pixel signal, readout selection switch element SE11 is turned ON and the reset component is outputted to signal line 180 via amplifier transistor SF 174 and selection transistor SEL_DET. Likewise, readout selection switch element SE12 is turned ON and the signal component is outputted to signal line 180 via amplifier transistor SF 174 and selection transistor SEL_DET.

Since the reset component is subtracted from the signal component by the CDS in AD converter 160, a variation in circuit such as amplifier transistor SF 81 or amplifier transistor SF 174 is canceled out.

Detection circuit 172 includes comparator 181, inverter circuit 182, latch circuit 183, inverter circuit 184, AND circuit 185, latch circuit 186, latch circuit 187, selection control circuit 188, SW13, SW14, SW15, SW16, and SW17.

Detection circuit 172 temporally continuously switches between the first reference value (REF1) and the second reference value (REF2) and input the first reference value or the second reference value to one end of input of comparator 181 by controlling SW15 and SW16 according to reference value selection signal 176.

First, detection circuit 172 temporally inputs the reset component included in the second pixel signal to another end of the input of comparator 181 and performs auto zero (turn SW13 and SW17 ON). Then, detection circuit 172 inputs the signal component included in the second pixel signal to the other end of the input of comparator 181 (turns SW14 ON), performs analog CDS, and compares a difference obtained by subtracting the signal component included in the second pixel signal from the reset component included in the second pixel signal and the first reference value (REF1) or the second reference value (REF2).

In the case where the optimal pixel signal is the first pixel signal, when the first reference value (REF1) is inputted, output of comparator 181 is logic level low (L), output of inverter circuit 182 is logic level high (H), output of latch circuit 183 is logic level high (H), and output of inverter circuit 184 is logic level low (L). Next, when the second reference value (REF2) is inputted, latch circuit 186 and latch circuit 187 are reset, the output of comparator 181 remains logic level low (L), the output of inverter circuit 182 remains logic level high (H), the output of latch circuit 183 remains logic level high (H), and output of AND circuit 185 is logic level low (L). For this reason, output of latch circuit 186 is logic level low (L), the output of latch circuit 183 is logic level high (H), and output of latch circuit 187 is logic level low (L). Based on the output of latch circuit 186, latch circuit 183, and latch circuit 187, selection control circuit 188 causes selection circuit 171 to output, as signal selection signal 175 ((φSE), a logic level high (H) signal of SE7 and SE8 that is an output signal of latch circuit 183, and output the reset component included in the first pixel signal to signal line 180 via amplifier transistor SF 174 and selection transistor SEL_DET. In a similar manner, selection control circuit 188 causes selection circuit 171 to output the signal component included in the first pixel signal to signal line 180 via amplifier transistor SF 174 and selection transistor SEL_DET. Next, since the second pixel signal is the corrective pixel signal, selection control circuit 188 causes selection circuit 171 to output, as signal selection signal 175 ((φSE), a logic level high (H) signal of SE9 and SE10 that is an output signal of latch circuit 183, and output the reset component included in the second pixel signal to signal line 180 via amplifier transistor SF 174 and selection transistor SEL_DET. In a similar manner, selection control circuit 188 causes selection circuit 171 to output the signal component included in the second pixel signal to signal line 180 via amplifier transistor SF 174 and selection transistor SEL_DET.

In the case where the optimal pixel signal is the second pixel signal, when the first reference value (REF1) is inputted, output of comparator 181 is logic level high (H), output of inverter circuit 182 is logic level low (L), output of latch circuit 183 is logic level low (L), and output of inverter circuit 184 is logic level high (H). Next, when the second reference value (REF2) is inputted, latch circuit 186 and latch circuit 187 are reset, the output of comparator 181 remains logic level low (L), the output of inverter circuit 182 remains logic level high (H), the output of latch circuit 183 remains logic level low (L), and output of AND circuit 185 is logic level high (H). For this reason, output of latch circuit 186 is logic level low (L), the output of latch circuit 183 is logic level low (L), and output of latch circuit 187 is logic level high (H). Based on the output of latch circuit 186, latch circuit 183, and latch circuit 187, selection control circuit 188 causes selection circuit 171 to output, as signal selection signal 175 ((φSE), a logic level high (H) signal of SE9 and SE10 that is an output signal of latch circuit 187, and output the reset component included in the second pixel signal to signal line 180 via amplifier transistor SF 174 and selection transistor SEL_DET. In a similar manner, selection control circuit 188 causes selection circuit 171 to output the signal component included in the second pixel signal to signal line 180 via amplifier transistor SF 174 and selection transistor SEL_DET. Next, since the third pixel signal is the corrective pixel signal, selection control circuit 188 causes selection circuit 171 to output, as signal selection signal 175 ((φSE), a logic level high (H) signal of SE11 and SE12 that is an output signal of latch circuit 187, and output the reset component included in the third pixel signal to signal line 180 via amplifier transistor SF 174 and selection transistor SEL_DET. In a similar manner, selection control circuit 188 causes selection circuit 171 to output the signal component included in the third pixel signal to signal line 180 via amplifier transistor SF 174 and selection transistor SEL_DET.

In the case where the optimal pixel signal is the third pixel signal, when the first reference value (REF1) is inputted, output of comparator 181 is logic level high (H), output of inverter circuit 182 is logic level low (L), output of latch circuit 183 is logic level low (L), and output of inverter circuit 184 is logic level high (H). Next, when the second reference value (REF2) is inputted, latch circuit 186 and latch circuit 187 are reset, the output of comparator 181 remains logic level high (H), the output of inverter circuit 182 remains logic level low (L), the output of inverter circuit 183 remains logic level low (L), and output of AND circuit 185 is logic level low (L). For this reason, output of latch circuit 186 is logic level high (H), the output of latch circuit 183 is logic level low (L), and output of latch circuit 187 is logic level low (L). Based on the output of latch circuit 186, latch circuit 183, and latch circuit 187, selection control circuit 188 causes selection circuit 171 to output, as signal selection signal 175 ((φSE), a logic level high (H) signal of SE11 and SE12 that is an output signal of latch circuit 186, and output the reset component included in the third pixel signal to signal line 180 via amplifier transistor SF 174 and selection transistor SEL_DET. In a similar manner, selection control circuit 188 causes selection circuit 171 to output the signal component included in the third pixel signal to signal line 180 via amplifier transistor SF 174 and selection transistor SEL_DET.

Additionally, the output of latch circuit 186, latch circuit 183, and latch circuit 187 is also inputted as gain selection signal 189 to AD converter 160. Based on a value of gain selection signal 189, AD converter 160 adds information for identifying a gain corresponding to an optimal pixel signal to a digital signal (hereinafter also referred to as an optimal digital signal) obtained after AD conversion is performed on the optimal pixel signal, and adds information for identifying a gain corresponding to a corrective pixel signal to a digital signal (hereinafter also referred to as a corrective digital signal) obtained after AD conversion is performed on the corrective pixel signal.

Accordingly, since selective reading for reading out at least one pixel signal from among a plurality of pixel signals is performed without performing redundant reading for reading out all the plurality of pixel signals, it is possible to achieve both high speed and low power in a subsequent stage including AD converters 160.

Although the present embodiment is described based on the premise that selection detection circuit 170 outputs a corrective pixel signal to signal line 180 after outputting an optimal pixel signal to signal line 180, selection detection circuit 170 may output a corrective pixel signal to signal line 180 before outputting an optimal pixel signal to signal line 180.

When a pixel signal is selected from among a plurality of pixel signals, as indicated by the SN level in FIG. 6 and FIG. 7, there is a great change in SN in a boundary between the first pixel signal and the second pixel signal and a boundary between the second pixel signal and the third pixel signal. For this reason, in spite of the same subject, a change in SN can occur depending on which gain is selected.

As a measure for this possibility, HDR synthesis circuit 140 mitigates a difference in SN in a boundary between an optimal digital signal and a corrective digital signal by mixing (blending) the optimal digital signal and the corrective digital signal just before the boundary.

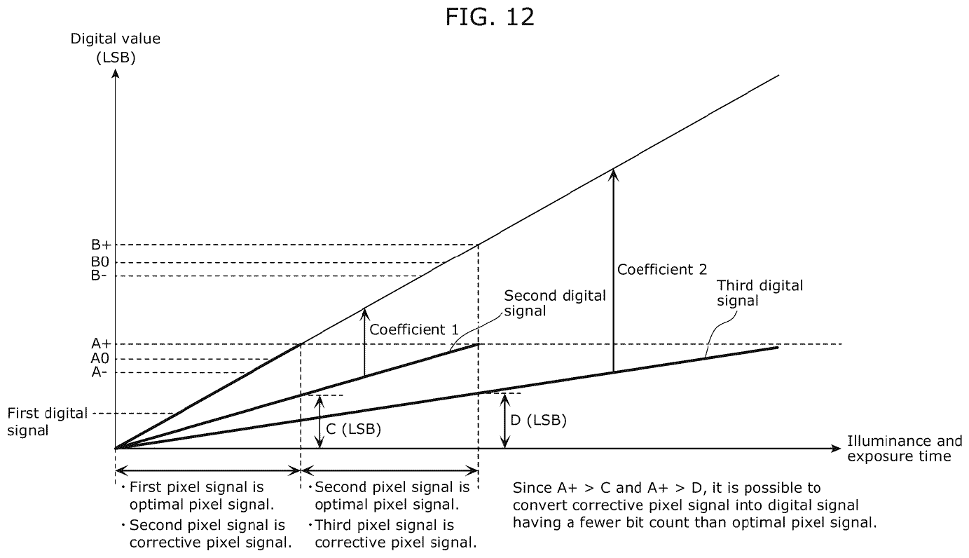

FIG. 12 is a graph in which the horizontal axis represents a product of an illuminance and an exposure time and the vertical axis represents a value (LSB as a unit) of a digital signal obtained after AD conversion is performed on a pixel signal, and which shows a relation between (i) a product of an illuminance and an exposure time and (ii) values of digital signals (hereinafter also referred to as a first digital signal, a second digital signal, and a third digital signal) obtained after AD conversion is performed on a first pixel signal, a second pixel signal, and a third pixel signal. As shown in FIG. 12, since a gain corresponding to a corrective pixel signal is lower than a gain corresponding to an optimal pixel signal, in a range of the amount of light in which the optimal pixel signal is not saturated, a value of a digital signal obtained after AD conversion is performed on the corrective pixel signal is less than a value of a digital signal obtained after AD conversion is performed on the optimal pixel signal.

For example, when selection detection circuit 170 determines the first pixel signal and the second pixel signal to be the optimal pixel signal and the corrective pixel signal, respectively, a value of a corrective digital signal when a value of an optimal digital signal is a maximum value of A+(LSB) that can be expressed by a bit count of the optimal digital signal, that is, a maximum value of the corrective digital signal is C(LSB) that is less than A+(LSB). In addition, when selection detection circuit 170 determines the second pixel signal and the third pixel signal to be the optimal pixel signal and the corrective pixel signal, respectively, a value of a corrective digital signal when a value of an optimal digital signal is a maximum value of A+(LSB) that can be expressed by a bit count of the optimal digital signal, that is, a maximum value of the corrective digital signal is D(LSB) that is less than A+(LSB).

Accordingly, it is possible to cause a bit count of the corrective digital signal to be fewer than the bit count of the optima digital signal, and achieve both the high speed and the low power in the subsequent stage including AD converters 160.

When HDR synthesis circuit 140 receives a digital signal from AD converter 160, HDR synthesis circuit 140 determines whether the digital signal is the first digital signal, the second digital signal, or the third digital signal, based on information for identifying a gain added to the digital signal. When the digital signal is the second digital signal, HDR synthesis circuit 140 generates a fourth digital signal by multiplying the digital signal by coefficient 1; or when the digital signal is the third signal, HDR synthesis circuit 140 generates a fifth digital signal by multiplying the digital signal by coefficient 2. As a result, HDR synthesis circuit 140 makes it possible to mix an optimal digital signal and a corrective digital signal. Here, coefficient 1 is equal to a value obtained by dividing the slope of a line segment indicating a relation between a value of the first digital signal and a product of an illuminance and an exposure time by the slope of a line segment indicating a relation between a value of the second digital signal and a product of an illuminance and an exposure time in FIG. 12; and coefficient 2 is equal to a value obtained by dividing the slope of a line segment indicating a relation between the value of the first digital signal and the product of the illuminance and the exposure time by the slope of a line segment indicating a relation between a value of the third digital signal and a product of an illuminance and an exposure time in FIG. 12.

Here, A0 indicated by the vertical axis in FIG. 12 is a value of a boundary portion between the first digital signal and the fourth digital signal; A− is a digital signal value that is less than A0; A+ is a digital signal value that is greater than A0 and equal to saturation of the first digital signal; B0 is a value of a boundary portion between the fourth digital signal and the fifth digital signal; B− is a digital signal value that is less than B0; and B+ is a digital signal value that is greater than B0 and equal to saturation of the fourth digital signal.

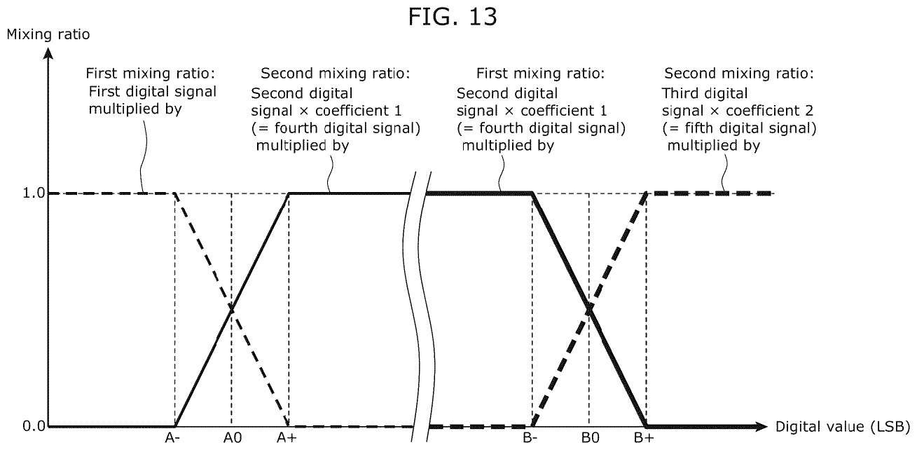

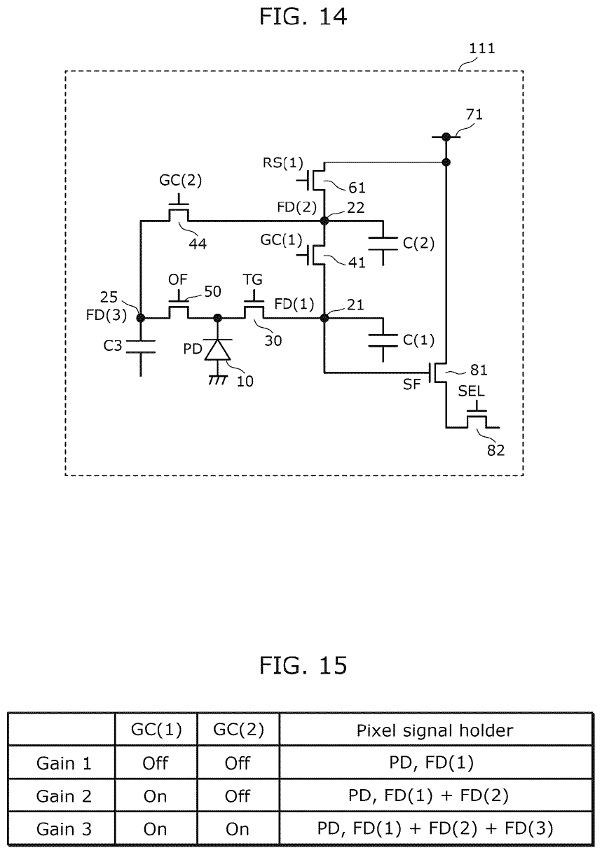

Next, when the optimal digital signal and the corrective digital signal are the first digital signal and the fourth digital signal, respectively, HDR synthesis circuit 140 mixes the optimal digital signal and the corrective digital signal by calculating the sum of a product of a first mixing ratio (a mixing ratio indicated by the thin dashed line in FIG. 13) and a value of the optimal digital signal and a product of a second mixing ratio (a mixing ratio indicated by the thin solid line in FIG. 13) and a value of the corrective digital signal.

Additionally, when the optimal digital signal and the corrective digital signal are the fourth digital signal and the fifth digital signal, respectively, HDR synthesis circuit 140 mixes the optimal digital signal and the corrective digital signal by calculating the sum of a product of the first mixing ratio (a mixing ratio indicated by the thick solid line in FIG. 13) and a value of the optimal digital signal and a product of the second mixing ratio (a mixing ratio indicated by the thick dashed line in FIG. 13) and a value of the corrective digital signal.

Here, as shown in FIG. 13, the sum of the first mixing ratio and the second mixing ratio is 1, and when the value of the first digital signal is less than A−, a value of the first mixing ratio is 1 and a value of the second mixing ratio is 0. When the value of the first digital signal is greater than or equal to A− and less than A+, the value of the first mixing ratio monotonically decreases with increase in the first digital signal, with a maximum value and a minimum value of the first mixing ratio being 1 and 0, respectively, and the value of the second mixing ratio monotonically increases with increase in the first digital signal, with a minimum value and a maximum value of the second mixing ratio being 0 and 1, respectively. When the value of the first digital signal is greater than or equal to A+, the value of the first mixing ratio is 0 and the value of the second mixing ratio is 1.

In addition, when a value of the fourth digital signal is less than B−, the value of the first mixing ratio is 1 and the value of the second mixing ratio is 0. When the value of the fourth digital signal is greater than or equal to B− and less than B+, the value of the first mixing ratio monotonically decreases with increase in the fourth digital signal, with a maximum value and a minimum value of the first mixing ratio being 1 and 0, respectively, and the value of the second mixing ratio monotonically increases with increase in the fourth digital signal, with a minimum value and a maximum value of the second mixing ratio being 0 and 1, respectively. When the value of the fourth digital signal is greater than or equal to B+, the value of the first mixing ratio is 0 and the value of the second mixing ratio is 1.

Accordingly, HDR synthesis circuit 140 makes it possible to mitigate the difference in SN in the boundary portion between the optimal digital signal and the corrective digital signal by gently mixing (blending) the optimal digital signal and the corrective digital signal in the boundary portion. Even when the bit count of the corrective digital signal is fewer than the bit count of the optimal digital signal, the above-described advantageous effect is not lost.

### <Control Timing Example 1 for Pixel>

Hereinafter, a control timing example for pixel 111 is described. The following description is based on the premise of M=3 and N=2 to avoid unnecessary overcomplication.

FIG. 14 is a circuit diagram showing a configuration example of pixel 111 when M=3 and N=2.

FIG. 15 is a correspondence table showing a correspondence relation between (1) three gains, (2) an ON state and an OFF state of connection transistor GC(1) and connection transistor GC(2) when pixel 111 is outputting a pixel signal corresponding to each of the three gains, and (3) FD(1) to FD(3) each of which holds a signal charge corresponding to the pixel signal, when M=3 and N=2.

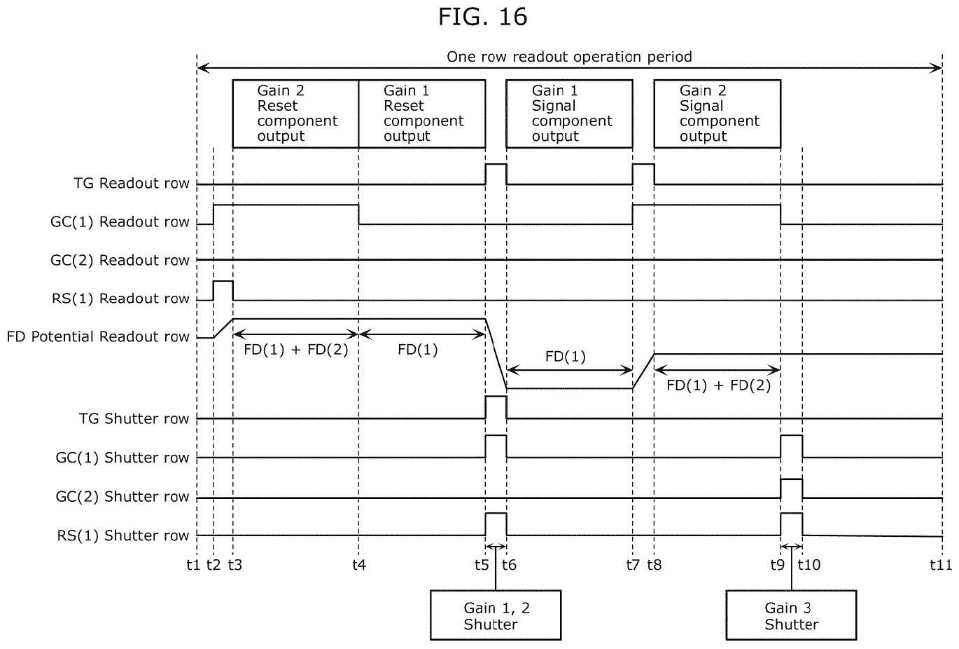

FIG. 16 is a timing chart showing an example of control timing for causing pixel 111 shown in FIG. 14 to output pixel signals corresponding to two gains including gain 1 and gain 2, when M=3 and N=2.

As shown in FIG. 16, a logic level of control signal GC(2) is always low in a readout row. For this reason, first connection transistor 44 is always OFF in the readout row.

At time t1, one row readout operation period starts.

At time t2, control circuit 130 causes vertical scanning circuit 120 to change logic levels of control signal RS(1) and control signal GC(1) from low to high in the readout row. Accordingly, in pixel 111, first reset transistor 61 and second connection transistor 41 change from OFF to ON, and voltages of FD(1) and FD(2) are equal to a voltage of first pixel power source 71. Consequently, in pixel 111, reset components included in pixel signals corresponding to gain 1 and gain 2 are generated.

At time t3, control circuit 130 causes vertical scanning circuit 120 to change the logic level of control signal RS(1) from high to low in the readout row. Accordingly, in pixel 111, first reset transistor 61 changes from ON to OFF.

From time t3 to time t4, pixel 111 causes FD(1) and FD(2) to output the reset component included in the pixel signal corresponding to gain 2 in the readout row. Vertical signal line 150 converges by time t4.

At time t4, control circuit 130 causes vertical scanning circuit 120 to change the logic level of control signal GC(1) from high to low in the readout row. Accordingly, in pixel 111, second reset transistor 41 changes from ON to OFF.

From time t4 to time t5, pixel 111 causes FD(1) to output the reset component included in the pixel signal corresponding to gain 1 in the readout row. Vertical signal line 150 converges by time t5.

At time t5, control circuit 130 causes vertical scanning circuit 120 to change a logic level of control signal TG from low to high in the readout row. Accordingly, in pixel 111, transfer transistor 30 changes from OFF to ON, and a signal charge accumulated in photoelectric converter 10 is transferred to FD(1). Consequently, in pixel 111, a signal component included in the pixel signal corresponding to gain 1 is generated.

On the other hand, control circuit 130 causes vertical scanning circuit 120 to change logic levels of control signal TG, control signal GC(1), and control signal RS(1) from low to high in a shutter row. Accordingly, in pixel 111, transfer transistor 30, second connection transistor 41, and first reset transistor 61 change from OFF to ON, a signal charge accumulated in photoelectric converter 10, a signal charge accumulated in FD(1), and a signal charge accumulated in FD(2) are discharged to first pixel power source 71.

It should be noted that, in the Specification, control that vertical scanning circuit 120 performs on pixel 111 in the shutter row is also referred to as shutter control. Moreover, in the Specification, an operation in which vertical scanning circuit 120 causes pixel 111 in the shutter row to discharge a signal charge to first pixel power source 71 (or second pixel power source 72 to be described later) is also referred to as a shutter operation.

At time t6, control circuit 130 causes vertical scanning circuit 120 to change the logic level of control signal TG from high to low in the readout row. Accordingly, in pixel 111, transfer transistor 30 changes from ON to OFF.

On the other hand, control circuit 130 causes vertical scanning circuit 120 to change the logic levels of control signal TG, control signal GC(1), and control signal RS(1) from high to low in the shutter row. Accordingly, in pixel 111, transfer transistor 30, second connection transistor 41, and first reset transistor 61 change from ON to OFF.

From time t6 to time t7, pixel 111 causes FD(1) to output the signal component included in the pixel signal corresponding to gain 1 in the readout row. Vertical signal line 150 converges by time t7.

At time t7, control circuit 130 causes vertical scanning circuit 120 to change the logic levels of control signal TG and control signal GC(1) from low to high in the readout row. Accordingly, in pixel 111, transfer transistor 30 and second connection transistor 41 change from OFF to ON. Consequently, in pixel 111, a signal component included in the pixel signal corresponding to gain 2 is generated.

It should be noted that since second connection transistor 41 is turned ON, at time t5, even when the signal charge is not completely transferred from photoelectric converter 10 to FD(1), at time t7, a capacitor of the transfer destination is expanded from capacitor C(1) to capacitor C(1)+capacitor C(2). For this reason, at time t5, the remaining signal charge that cannot be transferred from photoelectric converter 10 to FD(1) is transferred to FD(1) and FD(2).

At time t8, control circuit 130 causes vertical scanning circuit 120 to change the logic level of control signal TG from high to low in the readout row. Accordingly, in pixel 111, transfer transistor 30 changes from ON to OFF.

From time t8 to time t9, pixel 111 causes FD(1) and FD(2) to output the signal component included in the pixel signal corresponding to gain 2 in the readout row. Vertical signal line 150 converges by time t9.

At time t9, control circuit 130 causes vertical scanning circuit 120 to change the logic level of control signal GC(1) from high to low in the readout row. Accordingly, in pixel 111, second reset transistor 41 changes from ON to OFF.

On the other hand, control circuit 130 causes vertical scanning circuit 120 to change logic levels of control signal GC(1), control signal GC(2), and control signal RS(1) from low to high in the shutter row.

Accordingly, in pixel 111, first connection transistor 44, second connection transistor 41, and first reset transistor 61 change from OFF to ON, a signal charge accumulated in FD(3), a signal charge accumulated in FD(1), and a signal charge accumulated in FD(2) are discharged to first pixel power source 71.

In other words, in solid-state imaging device 100, even when pixel 111 outputs a signal charge corresponding to gain 1 and gain 2 and not based on the signal charge accumulated in FD(3) in the readout row, a signal charge accumulated in both photoelectric converter 10 and FD(3) is discharged to first pixel power source 71 in the shutter row. For this reason, charge accumulation times for photoelectric converter 10 and FD(3) are substantially equal to each other.

Accordingly, when types of two pixel signals outputted by each pixel 111 are changed from a pixel signal corresponding to gain 1 and a pixel signal corresponding to gain 2 to a pixel signal corresponding to gain 2 and a pixel signal corresponding to gain 3, it is possible to avoid abnormal image quality of the first frame after change.

At time t10, control circuit 130 causes vertical scanning circuit 120 to change the logic levels of control signal GC(1), control signal GC(2), and control signal RS(1) from high to low in the shutter row.

Accordingly, in pixel 111, first connection transistor 44, second connection transistor 41, first reset transistor 61 change from ON to OFF.

At time t11, the one row readout operation period ends.

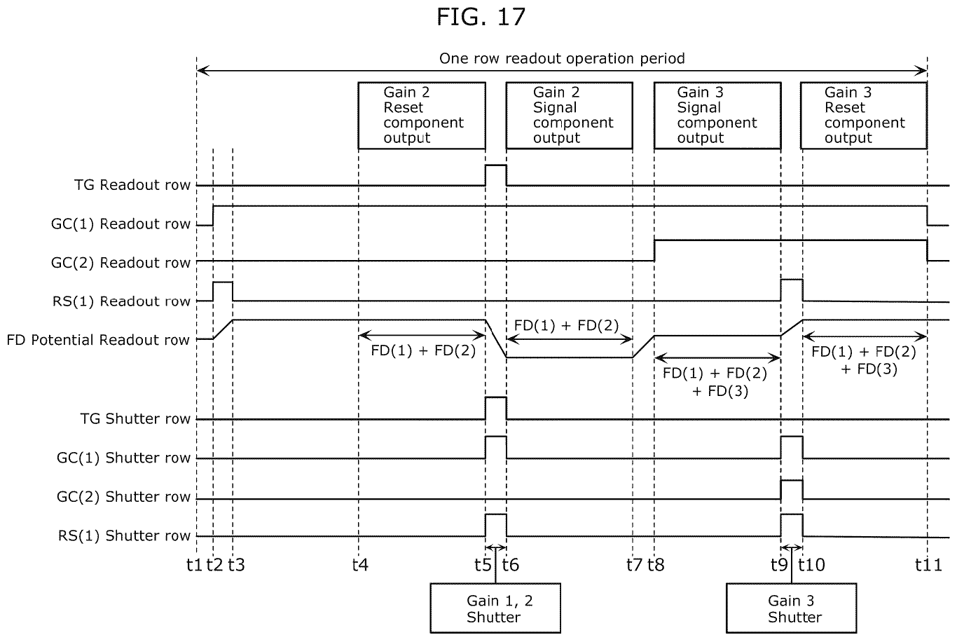

FIG. 17 is a timing chart showing an example of control timing for causing pixel 111 shown in FIG. 14 to output pixel signals corresponding to two gains including gain 2 and gain 3, when M=3 and N=2.

At time t1, one row readout operation period starts.

At time t2, control circuit 130 causes vertical scanning circuit 120 to change logic levels of control signal RS(1) and control signal GC(1) from low to high in a readout row. Accordingly, in pixel 111, first reset transistor 61 and second connection transistor 41 change from OFF to ON, and voltages of FD(1) and FD(2) are equal to a voltage of first pixel power source 71. Consequently, in pixel 111, reset components included in pixel signals corresponding to gain 1 and gain 2 are generated.

Here, a signal charge that overflows from photoelectric converter 10 during exposure is accumulated in FD(3). For this reason, from time t4 to time t5 to be described later, pixel 111 makes it possible to cause FD(1) and FD(2) to output a reset component included in the pixel signal corresponding to gain 2 in the readout row.

Accordingly, it is possible to obtain a favorable SN by performing correlated double sampling on the pixel signal corresponding to gain 2.

At time t3, control circuit 130 causes vertical scanning circuit 120 to change the logic level of control signal RS(1) from high to low in the readout row. Accordingly, in pixel 111, first reset transistor 61 changes from ON to OFF.

From time t4 to time t5, pixel 111 causes FD(1) and FD(2) to output the reset component included in the pixel signal corresponding to gain 2 in the readout row. Vertical signal line 150 converges by time t5.

At time t5, control circuit 130 causes vertical scanning circuit 120 to change a logic level of control signal TG from low to high in the readout row. Accordingly, in pixel 111, transfer transistor 30 changes from OFF to ON, and a signal charge accumulated in photoelectric converter 10 is transferred to FD(1) and FD(2). Consequently, in pixel 111, a signal component included in the pixel signal corresponding to gain 2 is generated.

On the other hand, control circuit 130 causes vertical scanning circuit 120 to change logic levels of control signal TG, control signal GC(1), and control signal RS(1) from low to high in a shutter row. Accordingly, in pixel 111, transfer transistor 30, second connection transistor 41, and first reset transistor 61 change from OFF to ON, a signal charge accumulated in photoelectric converter 10, a signal charge accumulated in FD(1), and a signal charge accumulated in FD(2) are discharged to first pixel power source 71.

At time t6, control circuit 130 causes vertical scanning circuit 120 to change the logic level of control signal TG from high to low in the readout row. Accordingly, in pixel 111, transfer transistor 30 changes from ON to OFF.

On the other hand, control circuit 130 causes vertical scanning circuit 120 to change the logic levels of control signal TG, control signal GC(1), and control signal RS(1) from high to low in the shutter row. Accordingly, in pixel 111, transfer transistor 30, second connection transistor 41, and first reset transistor 61 change from ON to OFF.

From time t6 to time t7, pixel 111 causes FD(1) and FD(2) to output the signal component included in the pixel signal corresponding to gain 2 in the readout row. Vertical signal line 150 converges by time t7.

At time t8, control circuit 130 causes vertical scanning circuit 120 to change a logic level of control signal GC(2) from high to low in the readout row. Accordingly, in pixel 111, first connection transistor 44 changes from OFF to ON.

For this reason, FD(3) that accumulates a signal charge that overflows from photoelectric converter 10 is electrically connected to FD(1) and FD(2) to which a signal charge is transferred from photoelectric converter 10 at time t8. Consequently, in pixel 111, a signal component included in the pixel signal corresponding to gain 3 is generated.

From time t8 to time t9, pixel 111 causes FD(1), FD(2), and FD(3) to output the signal component included in the pixel signal corresponding to gain 3 in the readout row. Vertical signal line 150 converges by time t9.

At time t9, control circuit 130 causes vertical scanning circuit 120 to change the logic level of control signal RS(1) from low to high in the readout row. Accordingly, in pixel 111, first reset transistor 61 changes from OFF to ON, a signal charge accumulated in FD(1), a signal charge accumulated in FD(2), and a signal charge accumulated in FD(3) are discharged to first pixel power source 71. Consequently, in pixel 111, a reset component included in the pixel signal corresponding to gain 3 is generated.

On the other hand, control circuit 130 causes vertical scanning circuit 120 to change logic levels of control signal GC(1), control signal GC(2), and control signal RS(1) from low to high in the shutter row. Accordingly, in pixel 111, first connection transistor 44, second connection transistor 41, and first reset transistor 61 change from OFF to ON, a signal charge accumulated in FD(3), a signal charge accumulated in FD(1), and a signal charge accumulated in FD(2) are discharged to first pixel power source 71.

At time t10, control circuit 130 causes vertical scanning circuit 120 to change the logic level of control signal RS(1) from high to low in the readout row. Accordingly, in pixel 111, first reset transistor 61 changes from ON to OFF.

On the other hand, control circuit 130 causes vertical scanning circuit 120 to change the logic levels of control signal GC(1), control signal GC(2), and control signal RS(1) from high to low in the shutter row. Accordingly, in pixel 111, first connection transistor 44, second connection transistor 41, first reset transistor 61 change from ON to OFF.

From time t10 to time t11, pixel 111 causes FD(1), FD(2), and FD(3) to output the reset component included in the pixel signal corresponding to gain 3 in the readout row. Vertical signal line 150 converges by time t11.

At time t11, the one row readout operation period ends.

According to solid-state imaging device 100 thus configured, pixel signals outputted by each pixel 111 are N pixel signals that are included in and less numerous than M pixel signals. For this reason, a pixel signal readout time is short, compared to a conventional solid-state image device including a configuration in which each of pixels outputs all of M pixel signals.

Accordingly, among solid-state imaging devices each including a pixel array in which a plurality of pixels each of which outputs M pixel signals each of which has a different gain are arranged in rows and columns, solid-state imaging device 100 thus configured makes it possible to achieve both speed-up of a frame rate and optimal dynamic range control.

### <Exposure Control in Imaging Apparatus>

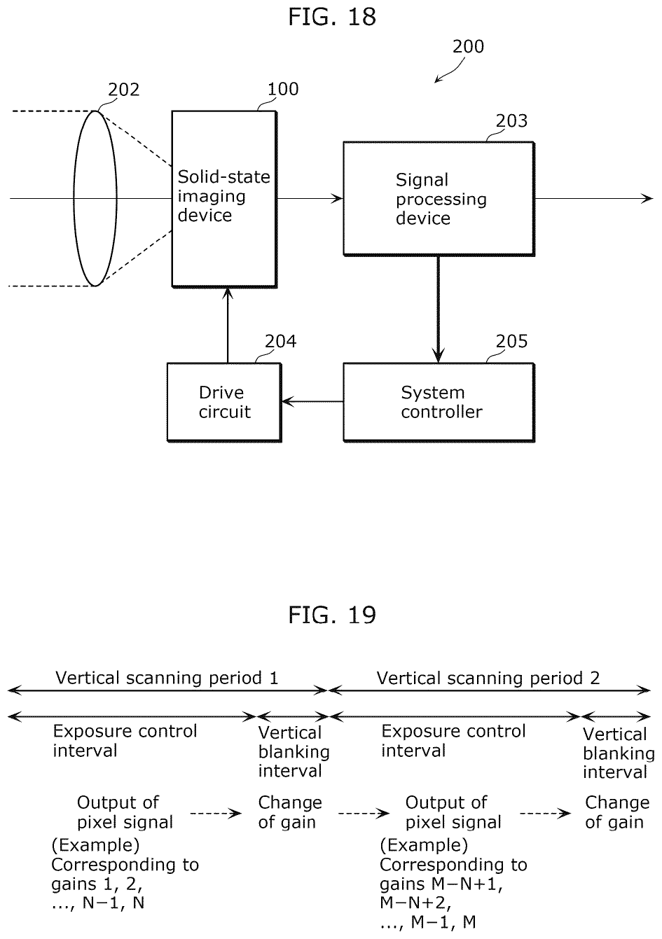

FIG. 18 is a block diagram showing a configuration example of imaging apparatus 200 according to Embodiment 1.

Imaging apparatus 200 is a camera system that includes solid-state imaging device 100.

As shown in FIG. 18, imaging apparatus 200 includes solid-state imaging device 100, solid-state optical system 202, signal processing unit 203, drive circuit 204, and system controller 205.

Solid-state optical system 202 includes a lens and focuses light from a subject on the surface of pixel array 110 of solid-state imaging device 100.

As state above, solid-state imaging device 100 sequentially outputs image data based on N pixel signals outputted by each of the plurality of pixels 111.

System controller 205 sequentially outputs, based on the image data sequentially outputted from solid-state imaging device 100, a gain specification signal for specifying which N pixel signals each pixel 111 is caused to output in control performed on each pixel 111 by vertical scanning circuit 120 of solid-state imaging device 100.

In addition, system controller 205 performs exposure control on solid-state imaging device 100.

Drive circuit 204 drives solid-state imaging device 100, based on the gain specification signal sequentially outputted from system controller 205. Accordingly, solid-state imaging device 100 sequentially outputs the image data based on the N pixel signals specified by the gain specification signal.

Signal processing unit 203 performs various types of signal processing on pixel signals outputted from solid-state imaging device 100.

FIG. 19 is a timing chart showing an example of timing for exposure control performed on solid-state imaging device 100 by system controller 205.

As shown in FIG. 19, system controller 205 performs exposure control on the same cycle as a vertical scanning period.

Additionally, system controller 205 further performs vertical blanking control on the same cycle as the vertical scanning period.

The vertical blanking control is control for causing solid-state imaging device 100 to change N pixel signals to be selected in a next vertical scanning period.

Imaging apparatus 200 thus configured makes it possible to achieve both speed-up of a frame rate and selection of an appropriate dynamic range.

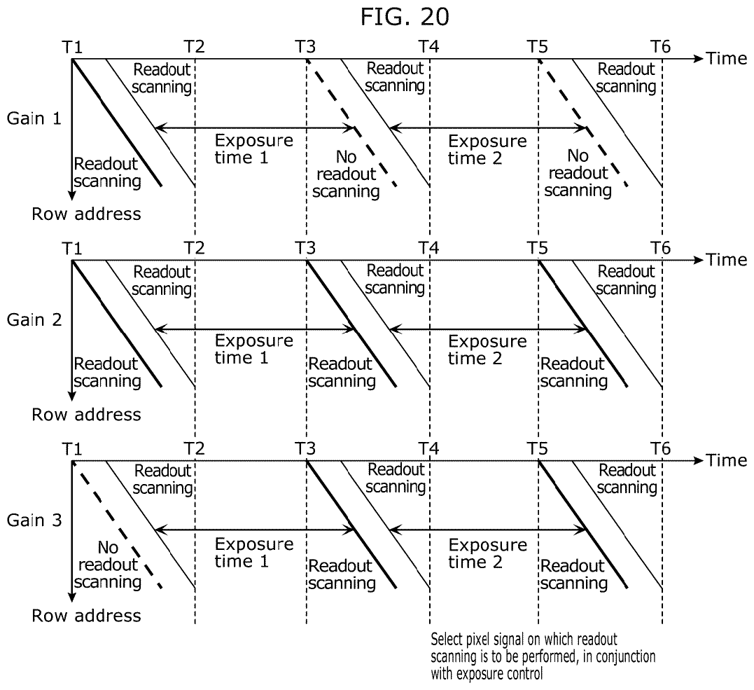

FIG. 20 is a timing chart showing a state in which, by system controller 205 controlling solid-state imaging device 100 in imaging apparatus 200, each pixel 111 outputs two pixel signals corresponding to gain 1 and gain 2 for a lower illuminance from time T1 to time T2, and outputs two pixel signals corresponding to gain 2 and gain 3 for a higher illuminance after time T3.

As shown in FIG. 20, from time T1 to time T2, pixel 111 does not output the pixel signal corresponding to gain 3 by scanning a readout row, but discharges, to first pixel power source 71, a signal charge for generating the pixel signal corresponding to gain 3 and accumulated in FD(3), by scanning a shutter row.

Accordingly, an exposure time for the pixel signal corresponding to gain 3 and outputted by pixel 111 from time T3 to time T4 is equal to an exposure time for the pixel signal corresponding to gain 2 and outputted by pixel 111 from time T3 to time T4.

Consequently, it is possible to avoid abnormal image quality of pixel data after HDR synthesis.

A solid-state imaging device (also referred to as “a solid-state imaging device according to a comparative example”) configured not to discharge signal charges corresponding to pixel signals other than selected N pixel signals and in a capacitance accumulator, by a shutter operation before a readout operation, discharges those signal charges by a shutter operation after the readout operation. For this reason, in the solid-state imaging device according to the comparative example, a frame rate is delayed by one frame, compared to solid-state imaging device 100 thus configured.

Solid-state imaging device 100 thus configured makes it possible to reduce the delay of the frame rate by one frame that occurs in the solid-state imaging device according to the comparative example, and speed up the frame rate, compared to the solid-state imaging device according to the comparative example.

It should be noted that Embodiment 1 is described on the premise that solid-state imaging device 100 repeatedly performs, for each row, scanning of a readout row and scanning of a shutter row on a one horizontal scanning period basis, solid-state imaging device 100 need not be limited to this configuration.

For example, solid-state imaging device 100 may scan a plurality of readout rows and a plurality of shutter rows in the same time period or may perform scanning in a global shutter mode in which signal charges in all the rows are discharged to first pixel power source 71, exposure is started, and pixel signals in all the rows are read out in the same time period after the completion of the exposure.

### Embodiment 2

Hereinafter, a solid-state imaging device according to Embodiment 2 configured by partially changing the configuration of solid-state imaging device 100 according to Embodiment 1 is described.

Here, constituent elements of the solid-state imaging device according to Embodiment 2 that are common to solid-state imaging device 100 are assigned the same reference signs, and the detailed description thereof is omitted, as they have already been described. The following description focuses mainly on differences from solid-state imaging device 100.

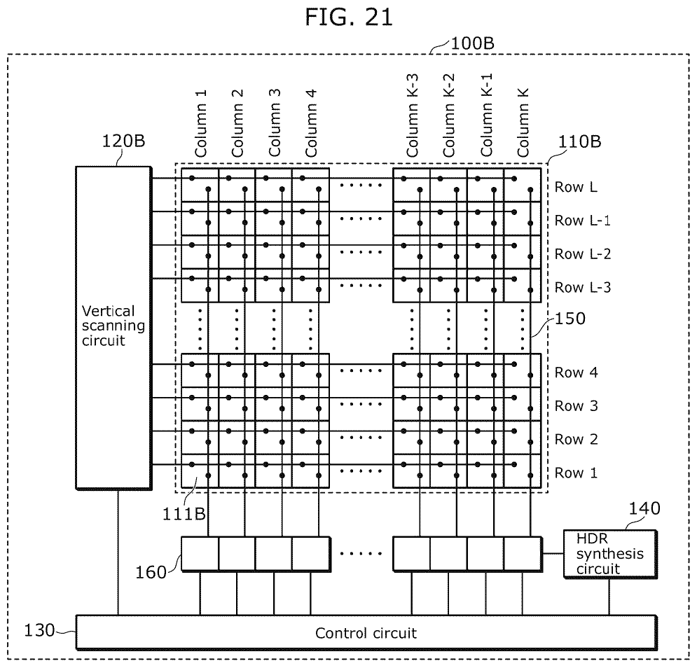

FIG. 21 is a block diagram showing a configuration example of solid-state imaging device 100B according to Embodiment 2.

As shown in FIG. 21, solid-state imaging device 100B is configured by replacing pixel array 110 and vertical scanning circuit 120 in solid-state imaging device 100 according to Embodiment 1 with pixel array 110B and vertical scanning circuit 120B, respectively.

Pixel array 110B is configured by replacing pixels 111 in pixel array 110 with pixels 111B.

Vertical scanning circuit 120B is configured by changing pixels to be controlled by vertical scanning circuit 120 from pixels 111 to pixels 111B.

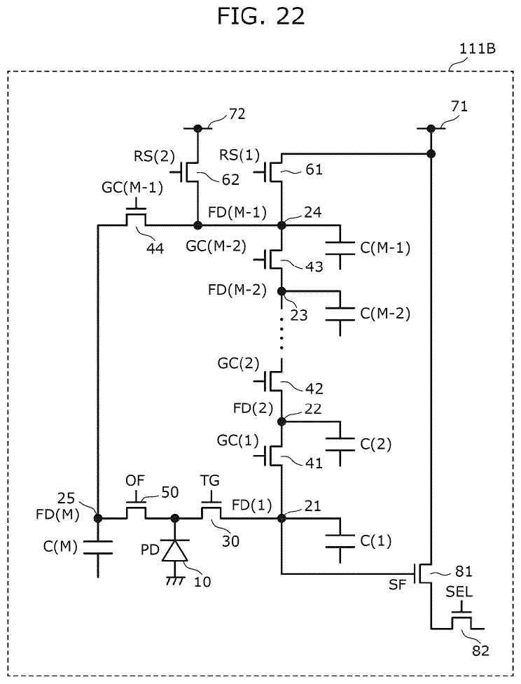

FIG. 22 is a circuit diagram showing a configuration example of pixel 111B.

As shown in FIG. 22, pixel 111B is configured by adding second reset transistor 62 to pixel 111.

Second reset transistor 62 includes a source and a drain, one of which is connected to the other of the source or the drain of first connection transistor 44 and an other of which is connected to second pixel power source 72. Here, a voltage of second pixel power source 72 is different from a voltage of first pixel power source 71.

Second reset transistor 62 is an NMOS transistor, and the gate of second reset transistor 62 is driven by control signal RS(2) outputted from vertical scanning circuit 120B.

When a logic level of the gate of second reset transistor 62 becomes low, second reset transistor 62 enters the non-conductive state; and when the logic level of the gate of second reset transistor 62 becomes high, second reset transistor 62 enters the conductive state.

Pixel 111B thus configured makes it possible to discharge signal charges accumulated in floating diffusion 21 to floating diffusion 24 and photoelectric converter 10 to first pixel power source 71, that is, reset floating diffusion 21 to floating diffusion 24 and photoelectric converter 10 at the voltage of first pixel power source 71, and discharge a signal charge accumulated in overflow capacitance accumulator 25 to second pixel power source 72, that is, reset overflow capacitance accumulator 25 at the voltage of second pixel power source 72.

Here, although it is necessary to cause a voltage to be applied to the gate of first connection transistor 44 to be higher than or equal to the voltage of second pixel power source 72 by causing the voltage of second pixel power source 72 to be lower than the voltage of first pixel power source 71, it is possible to discharge the signal charge accumulated in overflow capacitance accumulator 25 to second pixel power source 72 by causing the voltage to be applied to the gate of first connection transistor 44 to be lower than the voltage of first pixel power source 71.

For this reason, pixel 111B makes it easy to discharge the signal charge from overflow capacitance accumulator 25 at the time of a shutter operation, compared to pixel 111 configured to discharge the signal charges accumulated in floating diffusion 21 to floating diffusion 24, photoelectric converter 10, and overflow capacitance accumulator 25 to first pixel power source 71.

Accordingly, solid-state imaging device 100B thus configured reduces residual images when images are continuously captured, and improves dark signal non-uniformity, compared to solid-state imaging device 100.

In addition, solid-state imaging device 100B thus configured makes it possible to improve the reliability of vertical scanning circuit 120B that drives a gate voltage of first connection transistor 44, by causing the voltage of second pixel power source 72 to be lower than the voltage of first pixel power source 71.

### <Control Timing Example 2 for Pixel>

Hereinafter, a control timing example for pixel 111B is described. The following description is based on the premise of M=3 and N=2 to avoid unnecessary overcomplication.

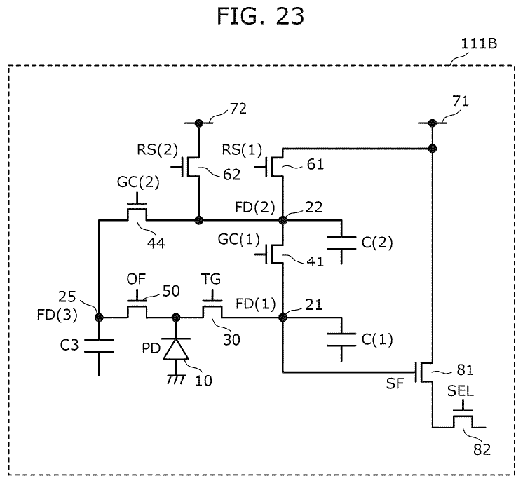

FIG. 23 is a circuit diagram showing a configuration example of pixel 111B when M=3 and N=2.

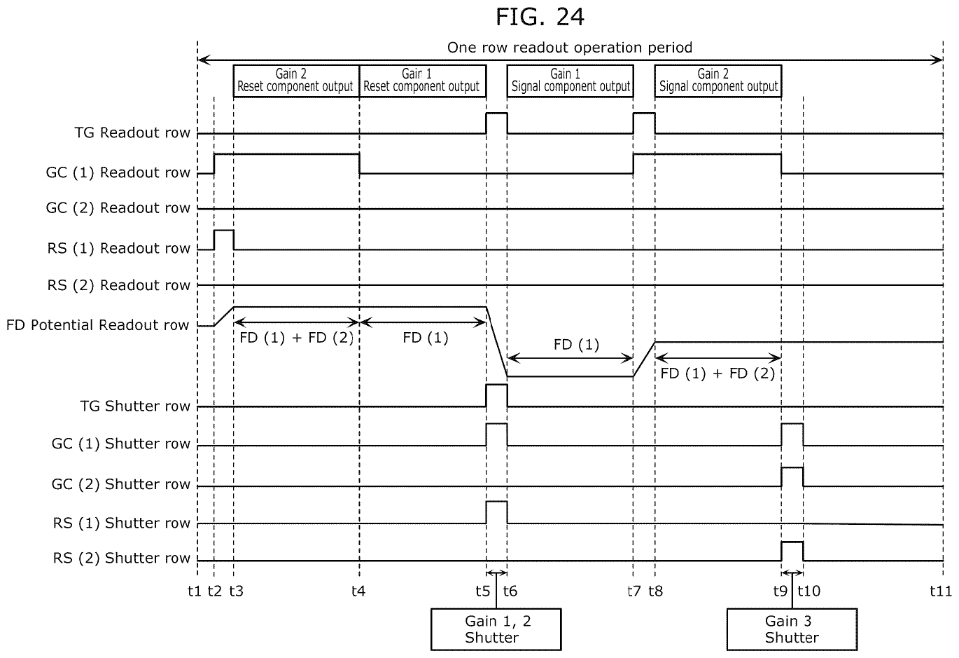

FIG. 24 is a timing chart showing an example of control timing for causing pixel 111B shown in FIG. 23 to output pixel signals corresponding to two gains including gain 1 and gain 2, when M=3 and N=2.

As shown in FIG. 24, logic levels of control signal GC(2) and control signal RS(2) are always low in a readout row. For this reason, first connection transistor 44 and second reset transistor 62 are always OFF in the readout row.

As shown in FIG. 24, the control timing for pixel 111B in the timing chart shown in FIG. 24 is identical to the control timing for pixel 111 in the timing chart shown in FIG. 16 in which pixel 111, vertical scanning circuit 120, and solid-state imaging device 100 are replaced with pixel 111B, vertical scanning circuit 120B, and solid-state imaging device 100B, respectively, except for a period from time t9 to time t10.

For this reason, regarding the control timing for pixel 111B in the timing chart shown in FIG. 24, the following description focuses mainly on operations in the period from time t9 to time t10.

At time t9, control circuit 130 causes vertical scanning circuit 120B to change a logic level of control signal GC(1) from high to low in the readout row. Accordingly, in pixel 111B, second reset transistor 41 changes from ON to OFF.

On the other hand, control circuit 130 causes vertical scanning circuit 120B to change logic levels of control signal GC(1), control signal GC(2), and control signal RS(2) from low to high in a shutter row. Accordingly, in pixel 111B, first connection transistor 44, second connection transistor 41, and second reset transistor 62 change from OFF to ON, a signal charge accumulated in FD(3), a signal charge accumulated in FD(1), and a signal charge accumulated in FD(2) are discharged to second pixel power source 72.

In other words, in solid-state imaging device 100B, even when pixel 111B outputs signal charges corresponding to gain 1 and gain 2 and not based on the signal charge accumulated in FD(3) in the readout row, a signal charge accumulated in both photoelectric converter 10 and FD(3) is discharged to second pixel power source 72 in the shutter row. For this reason, charge accumulation times for photoelectric converter 10 and FD(3) are substantially equal to each other.

Accordingly, when types of two pixel signals outputted by each pixel 111B are changed from a pixel signal corresponding to gain 1 and a pixel signal corresponding to gain 2 to a pixel signal corresponding to gain 2 and a pixel signal corresponding to gain 3, it is possible to avoid abnormal image quality of the first frame after change.

At time t10, control circuit 130 causes vertical scanning circuit 120B to change the logic levels of control signal GC(1), control signal GC(2), and control signal RS(2) from high to low in the shutter row. Accordingly, in pixel 111B, first connection transistor 44, second connection transistor 41, second reset transistor 62 change from ON to OFF.

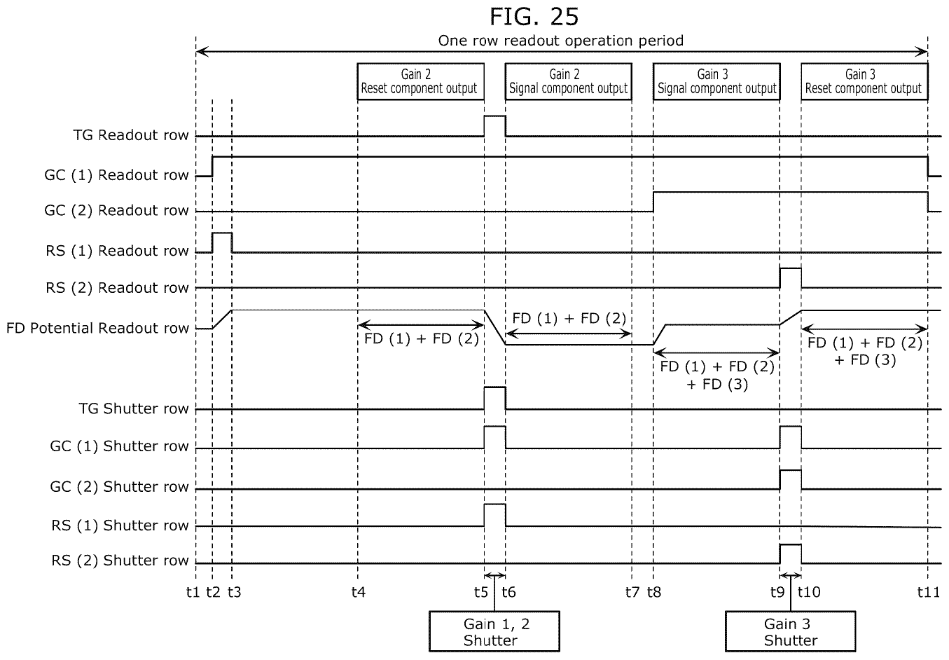

FIG. 25 is a timing chart showing an example of control timing for causing pixel 111B shown in FIG. 23 to output pixel signals corresponding to two gains including gain 1 and gain 2, when M=3 and N=2.

As shown in FIG. 25, the control timing for pixel 111B in the timing chart shown in FIG. 25 is identical to the control timing for pixel 111 in the timing chart shown in FIG. 17 in which pixel 111, vertical scanning circuit 120, and solid-state imaging device 100 are replaced with pixel 111B, vertical scanning circuit 120B, and solid-state imaging device 100B, respectively, except for a period from time t9 to time t10.

For this reason, regarding the control timing for pixel 111B in the timing chart shown in FIG. 25, the following description focuses mainly on operations in the period from time t9 to time t10.

At time t9, control circuit 130 causes vertical scanning circuit 120B to change a logic level of control signal RS(2) from low to high in a readout row. Accordingly, in pixel 111B, second reset transistor 62 changes from OFF to ON, a signal charge accumulated in FD(1), a signal charge accumulated in FD(2), and a signal charge accumulated in FD(3) are discharged to second pixel power source 72. Consequently, in pixel 111B, a reset component included in a pixel signal corresponding to gain 3 is generated.

On the other hand, control circuit 130 causes vertical scanning circuit 120B to change logic levels of control signal GC(1), control signal GC(2), and control signal RS(2) from low to high in a shutter row. Accordingly, in pixel 111B, first connection transistor 44, second connection transistor 41, and second reset transistor 62 change from OFF to ON, a signal charge accumulated in FD(3), a signal charge accumulated in FD(1), and a signal charge accumulated in FD(2) are discharged to second pixel power source 72.

At time t10, control circuit 130 causes vertical scanning circuit 120B to change the logic level of control signal RS(2) from high to low in the readout row. Accordingly, in pixel 111B, second reset transistor 62 changes from ON to OFF.

On the other hand, control circuit 130 causes vertical scanning circuit 120B to change the logic levels of control signal GC(1), control signal GC(2), and control signal RS(2) from high to low in the shutter row. Accordingly, in pixel 111B, first connection transistor 44, second connection transistor 41, second reset transistor 62 change from ON to OFF.

### Embodiment 3

Hereinafter, a solid-state imaging device according to Embodiment 3 configured by partially changing the configuration of solid-state imaging device 100 according to Embodiment 1 is described.

Here, constituent elements of the solid-state imaging device according to Embodiment 3 that are common to solid-state imaging device 100 are assigned the same reference signs, and the detailed description thereof is omitted, as they have already been described. The following description focuses mainly on differences from solid-state imaging device 100.

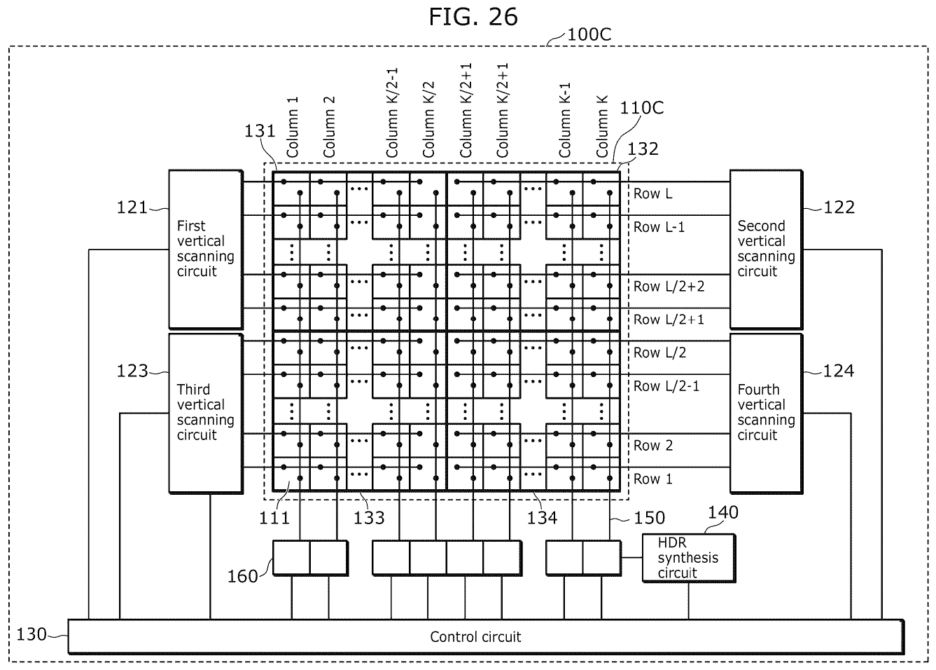

FIG. 26 is a block diagram showing a configuration example of solid-state imaging device 100C according to Embodiment 3.

As shown in FIG. 26, solid-state imaging device 100C is configured by replacing pixel array 110 and vertical scanning circuit 120 in solid-state imaging device 100 according to Embodiment 1 with pixel array 110C and first vertical scanning circuit 121, second vertical scanning circuit 122, third vertical scanning circuit 123, and fourth vertical scanning circuit 124, respectively.

Pixel array 110C is configured by causing pixel array 110 to include first pixel block 131, second pixel block 132, third pixel block 133, and fourth pixel block 134 arranged in rows and columns. First pixel block 131 includes a plurality of pixels 111 arranged in L/2 rows and K/2 columns, where L and K are even numbers. Second pixel block 132 includes a plurality of pixels 111 arranged in L/2 rows and K/2 columns. Third pixel block 133 includes a plurality of pixels 111 arranged in L/2 rows and K/2 columns. Fourth pixel block 134 includes a plurality of pixels 111 arranged in L/2 rows and K/2 columns.

In other words, first pixel block 131 includes a plurality of pixels 111 arranged in rows and columns in row L/2+1 to row L and column 1 to column K/2; second pixel block 132 includes a plurality of pixels 111 arranged in rows and columns in row L/2+1 to row L and column K/2+1 to column K; third pixel block 133 includes a plurality of pixels 111 arranged in rows and columns in row 1 to row L/2 and column 1 to column K/2; and fourth pixel block 134 includes a plurality of pixels 111 arranged in rows and columns in row 1 to row L/2 and column K/2+1 to column K.

First pixel block 131 may be referred to as first pixel array 131. Second pixel block 132 may be referred to as second pixel array 132. Third pixel block 133 may be referred to as third pixel array 133. Fourth pixel block 134 may be referred to as fourth pixel array 134.

First vertical scanning circuit 121 is configured by changing pixels to be controlled by vertical scanning circuit 120 from the plurality of pixels 111 included in pixel array 110 to the plurality of pixels 111 included in first pixel block 131.

Second vertical scanning circuit 122 is configured by changing pixels to be controlled by vertical scanning circuit 120 from the plurality of pixels 111 included in pixel array 110 to the plurality of pixels 111 included in second pixel block 132.

Third vertical scanning circuit 123 is configured by changing pixels to be controlled by vertical scanning circuit 120 from the plurality of pixels 111 included in pixel array 110 to the plurality of pixels 111 included in third pixel block 133.

Fourth vertical scanning circuit 124 is configured by changing pixels to be controlled by vertical scanning circuit 120 from the plurality of pixels 111 included in pixel array 110 to the plurality of pixels 111 included in fourth pixel block 134.

Solid-state imaging device 100C thus configured makes it possible to perform control for causing the plurality of pixels 111 included in first pixel block 131 to output any N pixel signals, control for causing the plurality of pixels 111 included in second pixel block 132 to output any N pixel signals, control for causing the plurality of pixels 111 included in third pixel block 133 to output any N pixel signals, and control for causing the plurality of pixels 111 included in fourth pixel block 134 to output any N pixel signals, independently of each other.

Accordingly, solid-state imaging device 100C thus configured makes it possible to achieve selection of a more appropriate dynamic range.

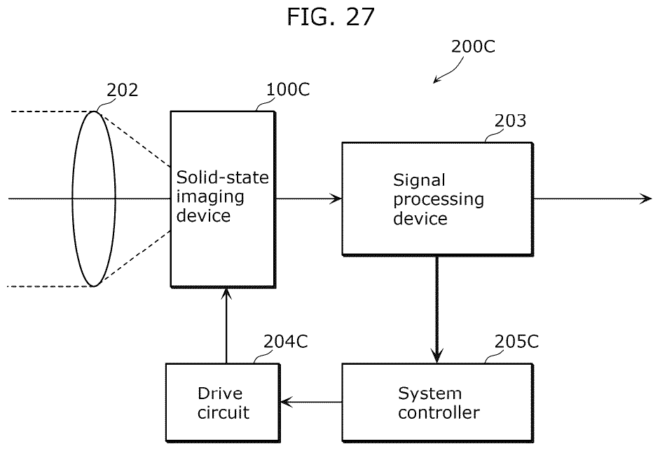

FIG. 27 is a block diagram showing a configuration example of imaging apparatus 200C according to Embodiment 3.

As shown in FIG. 27, imaging apparatus 200C is configured by replacing solid-state imaging device 100, system controller 205, and drive circuit 204 in imaging apparatus 200 according to Embodiment 1 with solid-state imaging device 100C, system controller 205C, and drive circuit 204C, respectively.

Based on image data sequentially outputted from solid-state imaging device 100C, system controller 205 sequentially outputs: a first gain specification signal for specifying which N pixel signals pixel 111 is caused to output in control of pixel 111 performed by first vertical scanning circuit 121 of solid-state imaging device 100C; a second gain specification signal for specifying which N pixel signals pixel 111 is caused to output in control of pixel 111 performed by second vertical scanning circuit 122; a third gain specification signal for specifying which N pixel signals pixel 111 is caused to output in control of pixel 111 performed by third vertical scanning circuit 123; and a fourth gain specification signal for specifying which N pixel signals pixel 111 is caused to output in control of pixel 111 performed by fourth vertical scanning circuit 124.

Drive circuit 204C drives solid-state imaging device 100C, based on the first gain specification signal, the second gain specification signal, the third gain specification signal, and the fourth gain specification signal sequentially outputted from system controller 205C.

Accordingly, imaging apparatus 200C thus configured makes it possible to achieve both speed-up of a frame rate and selection of an appropriate dynamic range at a higher level.

It should be noted that although Embodiment 3 is described based on the premise that the plurality of pixels included in pixel array 110C are pixels 111, the plurality of pixels included in pixel array 110C may be pixels 111B.

It should be noted that although Embodiment 3 is described based on the premise that pixel array 110C includes four pixel blocks of first pixel block 131, second pixel block 132, third pixel block 133, and fourth pixel block 144, pixel array 110C may include a plurality of pixel blocks and need not include four pixel blocks. For example, pixel array 110C may include two pixel blocks of first pixel block 131 and second pixel block 132 or may include more than four pixel blocks.

It should be noted that Embodiment 3 is described based on the premise that pixels 111 controlled by first vertical scanning circuit 121 are arranged in rows and columns in first pixel block 131, pixels 111 controlled by second vertical scanning circuit 122 are arranged in rows and columns in second pixel block 132, pixels 111 controlled by third vertical scanning circuit 123 are arranged in rows and columns in third pixel block 133, and pixels 111 controlled by fourth vertical scanning circuit 124 are arranged in rows and columns in fourth pixel block 134.

However, as long as pixels 111 controlled by first vertical scanning circuit 121 are disposed in pixel array 110C, pixels 111 may be disposed at any positions in pixel array 110C and need not be arranged in rows and columns in first pixel block 131. As long as pixels 111 controlled by second vertical scanning circuit 122 are disposed in pixel array 110C, pixels 111 may be disposed at any positions in pixel array 110C and need not be arranged in rows and columns in second pixel block 132. As long as pixels 111 controlled by third vertical scanning circuit 123 are disposed in pixel array 110C, pixels 111 may be disposed at any positions in pixel array 110C and need not be arranged in rows and columns in third pixel block 133. As long as pixels 111 controlled by fourth vertical scanning circuit 124 are disposed in pixel array 110C, pixels 111 may be disposed at any positions in pixel array 110C and need not be arranged in rows and columns in fourth pixel block 134.

### Supplement

Embodiment 1 to Embodiment 3 are described above as examples of the techniques disclosed in the Specification. However, the present disclosure is not limited to these embodiments. Forms obtained by various modifications to each of the embodiments that can be conceived by a person skilled in the art or forms realized by combining the constituent elements in different embodiments or variations may be included in the scope of one or more aspects of the present disclosure, as long as they do not depart from the gist of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to, for example, solid-state imaging devices that capture images.

1. A solid-state imaging device comprising:
a pixel array in which a plurality of pixels are arranged in rows and columns,
wherein each of the plurality of pixels includes:
a photoelectric converter that converts received light into a signal charge; and
a capacitance accumulator,
each of the plurality of pixels is configured to output M pixel signals each of which has a different gain, and
control is performed on each of the plurality of pixels to cause the pixel to output N pixel signals out of the M pixel signals, N being an integer that is at least 2 and less than M.

2. The solid-state imaging device according to claim 1,
wherein the capacitance accumulator includes:
an overflow capacitance accumulator for accumulating the signal charge that overflows from the photoelectric converter; and
at least one floating diffusion for converting the signal charge after conversion by the photoelectric converter into a voltage.

3. The solid-state imaging device according to claim 2,
wherein each of the plurality of pixels further includes:
a transfer transistor that includes a source and a drain, one of which is connected to the photoelectric converter and an other of which is connected to one of the at least one floating diffusion; and
a first connection transistor that includes a source and a drain, one of which is connected to the overflow capacitance accumulator and an other of which is connected to one of the at least one floating diffusion.

4. The solid-state imaging device according to claim 2,
wherein the control performed on each of the plurality of pixels includes shutter control for causing the pixel to perform a shutter operation, and
the shutter control is performed on each of the plurality of pixels to cause a period in which the overflow capacitance accumulator accumulates an electric charge and a period in which the photoelectric converter accumulates an electric charge to be substantially equal in length, regardless of the control performed on the pixel to cause the pixel to output the N pixel signals out of the M pixel signals.

5. The solid-state imaging device according to claim 3,
wherein each of the plurality of pixels further includes an overflow transistor that includes a source and a drain, one of which is connected to the photoelectric converter and an other of which is connected to the overflow capacitance accumulator.

6. The solid-state imaging device according to claim 3,
wherein the at least one floating diffusion includes a plurality of floating diffusions, and
each of the plurality of pixels further includes at least one second connection transistor that connects the plurality of floating diffusions.

7. The solid-state imaging device according to claim 3,
wherein each of the plurality of pixels further includes a first reset transistor that includes a source and a drain, one of which is connected to the other of the source or the drain of the first connection transistor and an other of which is connected to a first pixel power source.

8. The solid-state imaging device according to claim 7,
wherein each of the plurality of pixels further includes a second reset transistor that includes a source and a drain, one of which is connected to the other of the source or the drain of the first connection transistor and an other of which is connected to a second pixel power source that has a voltage different from a voltage of the first pixel power source.

9. The solid-state imaging device according to claim 1,
wherein the control is performed on each of the plurality of pixels to cause the pixel to output N pixel signals out of the M pixel signals, the N pixel signals having gains adjacent to each other.

10. A solid-state imaging device comprising:
a pixel array in which a plurality of pixels are arranged in rows and columns; and
an AD converter that is disposed for each of the columns in the pixel array,
wherein each of the plurality of pixels is configured to output M pixel signals each of which has a different gain, and
the AD converter converts each of at least one pixel signal out of the M pixel signals into a digital signal having a bit count fewer than a bit count of each of other pixel signals among the M pixel signals.

11. The solid-state imaging device according to claim 10, further comprising:
a selection detection circuit that is disposed for each of the columns in the pixel array,
wherein the selection detection circuit:
receives the M pixel signals from the pixel array; and
detects, among the M pixel signals, at least one pixel signal and at least one corrective pixel signal, and outputs the at least one pixel signal and the at least one corrective pixel signal to the AD converter, and
the AD converter converts the at least one pixel signal into a digital signal, and converts the at least one corrective pixel signal into a first corrective digital signal having a bit count fewer than a bit count of the digital signal.

12. The solid-state imaging device according to claim 11, further comprising:
a high dynamic range (HDR) synthesis circuit,
wherein the AD converter outputs the digital signal and the first corrective digital signal to the HDR synthesis circuit,
the HDR synthesis circuit:
generates a second corrective digital signal by multiplying a value of the first corrective digital signal by a coefficient; and
adds up a value obtained by multiplying a value of the digital signal by a first mixing ratio and a value obtained by multiplying a value of the second corrective digital signal by a second mixing ratio, and
a sum of the first mixing ratio and the second mixing ratio is 1.

13. A solid-state imaging device comprising:
a pixel array in which a plurality of pixels are arranged in rows and columns; and
an AD converter that is disposed for each of the columns in the pixel array,
wherein each of the plurality of pixels includes:
a photoelectric converter that converts received light into a signal charge; and
a capacitance accumulator,
each of the plurality of pixels is configured to output M pixel signals each of which has a different gain,
control is performed on each of the plurality of pixels to cause the pixel to output N pixel signals out of the M pixel signals, N being an integer that is at least 2 and less than M, and
the AD converter converts at least one pixel signal out of the N pixel signals into a digital signal having a bit count fewer than a bit count of each of other pixel signals among the N pixel signals.

14. The solid-state imaging device according to claim 1,
wherein the pixel array includes:
a plurality of pixel blocks; and
a control circuit that causes each of the plurality of pixel blocks to independently select and output the N pixel signals out of the M pixel signals,
each of the plurality of pixel blocks includes a plurality of first pixels that are arranged in rows and columns, and
the plurality of first pixels are included in the plurality of pixels.

15. An imaging apparatus comprising the solid-state imaging device according to claim 1,
wherein the solid-state imaging device sequentially outputs image data based on the N pixel signals outputted by each of the plurality of pixels,
the imaging apparatus further comprises a system controller that sequentially outputs, based on the image data sequentially outputted from the solid-state imaging device, a gain specification signal for specifying which N pixel signals each of the plurality of pixels is caused to output in the control performed on the pixel by the solid-state imaging device, and
the solid-state imaging device sequentially controls each of the plurality of pixels, based on the gain specification signal sequentially outputted from the system controller.

16. An imaging apparatus comprising the solid-state imaging device according to claim 14,
wherein the solid-state imaging device sequentially outputs image data based on the N pixel signals outputted by each of the plurality of pixels,
the imaging apparatus further comprises a system controller that sequentially outputs, based on the image data sequentially outputted from the solid-state imaging device, a gain specification signal for specifying which N pixel signals each of the plurality of first pixels included in a corresponding one of the plurality of pixel blocks is caused to output in control performed on each of the plurality of pixel blocks by the solid-state imaging device, the gain specification signal being a signal for the pixel block, and
the solid-state imaging device sequentially controls the first pixel included in the corresponding one of the plurality of pixel blocks, based on the gain specification signal for each of the plurality of pixel blocks sequentially outputted from the system controller.
